(19) United States
(12) Patent Application Publication
(10) Pub. No.: US 2024/0321959 A1
(43) Pub. Date: Sep. 26, 2024

(54) BACKSIDE CONTACT FORMATION

(71) Applicant: INTERNATIONAL BUSINESS MACHINES CORPORATION, ARMONK, NY (US)

(72) Inventors: Ruilong Xie, Niskayuna, NY (US); Shogo Mochizuki, Mechanicville, NY (US); Kisik Choi, Watervliet, NY (US); HUIMEI ZHOU, Albany, NY (US); Tenko Yamashita, Schenectady, NY (US)

(21) Appl. No.: 18/187,706

(22) Filed: Mar. 22, 2023

(51) Int. Cl. H01L 29/06; H01L 21/768; H01L 21/8238; H01L 27/092; H01L 29/423; H01L 29/66; H01L 29/775; H01L 29/786

(52) U.S. Cl. CPC H01L 29/0673; H01L 21/76843; H01L 21/823807; H01L 21/823814; H01L 21/823878; H01L 27/092; H01L 29/42392; H01L 29/66439; H01L 29/775; H01L 29/78696

(57) ABSTRACT

An upper portion of a source/drain epitaxy adjacent to channel layers of a nanosheet stack on a substrate, a lower portion of the source/drain epitaxy below the upper portion of the source/drain epitaxy, a second width of the lower portion of the source/drain epitaxy is greater than a first width of the upper portion of the source/drain epitaxy, a dielectric fill layer below the nanosheet stack, and a dielectric encapsulation liner between the dielectric fill layer and the lower portion of the source/drain epitaxy. Forming an upper portion of a source/drain epitaxy adjacent to semiconductor channel layers of a nanosheet stack, and forming a lower portion of the source/drain epitaxy below the upper portion of the source/drain epitaxy, a second width of the lower portion of the source/drain epitaxy is greater than a first width of the upper portion of the source/drain epitaxy.

### BACKGROUND

The present invention relates, generally, to the field of semiconductor manufacturing, and more particularly to a backside contact.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet device contains one or more layers of semiconductor channel material portions having a vertical thickness that is substantially less than its width. A nanosheet FET includes a plurality of stacked nanosheets extending between a pair of source/drain epitaxial regions. The device may be a gate all around device or transistor in which a gate surrounds a portion of the nanosheet channel. Backside contact integrity is important for good connections and avoidance of shorts.

### SUMMARY

According to an embodiment, a semiconductor device is provided. The semiconductor including an upper portion of a source drain epitaxy adjacent to semiconductor channel layers of a nanosheet stack on a substrate, and a lower portion of the source drain epitaxy below the upper portion of the source drain epitaxy, where a second width of the lower portion of the source drain epitaxy is greater than a first width of the upper portion of the source drain epitaxy.

According to an embodiment, a semiconductor device is provided. The semiconductor including an upper portion of a source drain epitaxy adjacent to channel layers of a nanosheet stack on a substrate, a lower portion of the source drain epitaxy below the upper portion of the source drain epitaxy, where a second width of the lower portion of the source drain epitaxy is greater than a first width of the upper portion of the source drain epitaxy, a dielectric fill layer below a lowest semiconductor channel layer of the nanosheet stack, and a dielectric encapsulation liner between the dielectric fill layer and the lower portion of the source drain epitaxy.

According to an embodiment, a method is provided. The method including forming an upper portion of a source drain epitaxy adjacent to semiconductor channel layers of a nanosheet stack on a substrate, and forming a lower portion of the source drain epitaxy below the upper portion of the source drain epitaxy, where a second width of the lower portion of the source drain epitaxy is greater than a first width of the upper portion of the source drain epitaxy.

### BRIEF DESCRIPTION OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a top view of a semiconductor structure at an intermediate stage of fabrication, according to an exemplary embodiment;

FIGS. 2, 3 and 4 each illustrate a cross-sectional view of the semiconductor structure of FIG. 1 along section line X-X, Y1-Y1 and Y2-Y2, respectively, according to an exemplary embodiment;

FIGS. 5, 6 and 7 each illustrate a cross-sectional view of the semiconductor structure along section line X-X, Y1-Y1 and Y2-Y2, respectively, and illustrate forming nanosheet stacks, forming a sacrificial gate and forming a shallow trench isolation, according to an exemplary embodiment;

FIGS. 8, 9 and 10 each illustrate a cross-sectional view of the semiconductor structure along section line X-X, Y1-Y1 and Y2-Y2, respectively, and illustrate forming a side spacer and an inner spacer, according to an exemplary embodiment;

FIGS. 11, 12 and 13 each illustrate a cross-sectional view of the semiconductor along section line X-X, Y1-Y1 and Y2-Y2, respectively, and illustrate forming a protective liner and a silicon recess, according to an exemplary embodiment;

FIGS. 14, 15 and 16 each illustrate a cross-sectional view of the semiconductor along section line X-X, Y1-Y1 and Y2-Y2, respectively, and illustrate forming a placeholder, according to an exemplary embodiment;

FIGS. 17, 18 and 19 each illustrate a cross-sectional view of the semiconductor along section line X-X, Y1-Y1 and Y2-Y2, respectively, and illustrate forming a source drain and an interlevel dielectric, according to an exemplary embodiment;

FIGS. 20, 21 and 22 each illustrate a cross-sectional view of the semiconductor along section line X-X, Y1-Y1 and Y2-Y2, respectively, and illustrate forming a gate cut, removing the sacrificial gate, replacement gate formation, forming a contact, forming a back-end of line interconnect and bonding a carrier wafer, according to an exemplary embodiment;

FIGS. 23, 24 and 25 each illustrate a cross-sectional view of the semiconductor along section line X-X, Y1-Y1 and Y2-Y2, respectively, and illustrate removal of portions of a substrate, according to an exemplary embodiment;

FIGS. 26, 27 and 28 each illustrate a cross-sectional view of the semiconductor along section line X-X, Y1-Y1 and Y2-Y2, respectively, and illustrate removal of a sacrificial layer, according to an exemplary embodiment;

FIGS. 29, 30 and 31 each illustrate a cross-sectional view of the semiconductor along section line X-X, Y1-Y1 and Y2-Y2, respectively, and illustrate removal of remaining portions of the substrate, according to an exemplary embodiment;

FIGS. 32, 33 and 34 each illustrate a cross-sectional view of the semiconductor along section line X-X, Y1-Y1 and Y2-Y2, respectively, and illustrate formation of a liner, according to an exemplary embodiment;

FIGS. 35, 36 and 37 each illustrate a cross-sectional view of the semiconductor along section line X-X, Y1-Y1 and Y2-Y2, respectively, and illustrate formation of a dielectric, according to an exemplary embodiment;

FIGS. 38, 39 and 40 each illustrate a cross-sectional view of the semiconductor along section line X-X, Y1-Y1 and Y2-Y2, respectively, and illustrate removal of the placeholder, according to an exemplary embodiment;

FIGS. 41, 42 and 43 each illustrate a cross-sectional view of the semiconductor along section line X-X, Y1-Y1 and Y2-Y2, respectively, and illustrate formation of an epitaxy, according to an exemplary embodiment;

FIGS. 44, 45 and 46 each illustrate a cross-sectional view of the semiconductor along section line X-X, Y1-Y1 and Y2-Y2, respectively, and illustrate formation of an inter-layer dielectric and formation of a contact, according to an exemplary embodiment; and

FIGS. 47, 48 and 49 each illustrate a cross-sectional view of the semiconductor along section line X-X, Y1-Y1 and Y2-Y2, respectively, and illustrate forming a backside power rail and a backside power delivery network, according to an exemplary embodiment.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numbers may be repeated among the figures to indicate corresponding or analogous features.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

A nanosheet field effect transistor (hereinafter “FET”) may be formed from alternating layers of silicon and silicon germanium, which are then formed into stacked nanosheets. A gate all around structure may be formed on all vertical sides and on a horizontal top surface of a section of the nanosheets. Source-drain structures may be formed at the opposite ends of the stacked nanosheet structures.

Proper alignment for direct backside contact patterning is challenging, and can be a problem when a BSCA (backside contact) critical dimension (CD) is too large or too small. When a BSCA has a CD which is too large, there is a chance of shorting between the BSCA to gate (PC) short, or a chance of shorting between a BSCA and a neighboring source drain which does not have a backside contact. For a BSCA CD which is too small, there is a chance that an overlap area of the BSCA to a source drain epitaxy is too small to provide good contact.

In an embodiment of this invention, a source drain epitaxy includes a frontside portion and a backside portion. The frontside portion of the source drain epitaxy is between channels of a nanosheet FET. The backside portion of the source drain epitaxy extends below the nanosheet FET and may be referred to as a sigma cavity epitaxy grown in a sigma cavity etch. The backside portion of the source drain epitaxy has a larger critical dimension (CD) than a CD the frontside portion of the source drain epitaxy. The CD of the backside portion of the source drain epitaxy is a width of the backside portion of the source drain epitaxy. The CD of the frontside portion of the source drain epitaxy is a width of the frontside portion of the source drain epitaxy. The larger CD of the backside portion of the source drain epitaxy increases an overlap contact area for forming a BSCA to the backside portion of the source drain epitaxy, improving reliability of the BSCA.

In an embodiment, a dielectric encapsulation liner separates a dielectric fill layer below the nanosheet FET from the backside portion of the source drain epitaxy. The dielectric encapsulation liner also separates the dielectric fill layer below the nanosheet FET from a lowermost channel layer of the nanosheet FET. This improves reliability by preventing excessive oxygen from the backside dielectric fill layer from diffusing into a gate stack.

In an embodiment, there is an airgap in the inter-layer dielectric below the nanosheet FET, between adjacent backside portions of the source drain epitaxy. The airgap helps provide capacitance reduction for overall RC reduction by forming airgap between intra-level metal line. The capacitance reduction will enhance device performance.

Forming the nanosheet FET may have the following steps. Layers of the stacked nanosheet are formed on a substrate. The substrate may have an embedded etch stop layer, trenches are formed parallel to each other in the layers of the stacked nanosheet to form fins and a shallow trench isolation formed in a substrate in the trenches. Sacrificial gates are then formed perpendicular to the trenches. Additional trenches are formed between sacrificial gates, perpendicular to the original trenches. Outer portions of sacrificial layers of the stacked nanosheets may be removed and inner spacers formed where the outer portions of the sacrificial layers of the stacked nanosheets where removed. A protective liner may be formed protecting a vertical side surface of the sacrificial gates, channel layers and inner spacers. A sigma cavity etch extends the additional trench by removing a portion of the substrate below the stacked nanosheets. The embedded etch stop layer provides a lower boundary for the sigma cavity etch. The sigma cavity has a wider width or CD than a width of the additional trench. The protective liner may be removed. A placeholder may be formed in the sigma cavity.

A frontside portions of a source drain are formed extending out from exposed channel layers of the nanosheet stacks over the placeholder. The sacrificial gates are removed, and remaining portions of the sacrificial layers are removed. Work function metal may be formed where the sacrificial gates and the remaining portions of the sacrificial layers were removed, surrounding the channel layers. Contacts may be formed to the work function metal and to the source drain. Further formation of back end of line (BEOL) layers of wiring and vias may be done.

A carrier substrate may be bonded to an upper surface of the formed nanosheet FET with BEOL layers, above the BEOL layers. The structure may be turned upside down for further processing. The substrate and the embedded etch stop layer may be removed. A liner may be formed. A dielectric fill layer may be formed which has air gaps. Portions of the liner, the STI and the dielectric fill layer may be removed. The placeholder may be removed. A backside portion of the source drain is formed where the placeholder was removed, extending from the frontside portion of the source drain. An inter-layer dielectric may be formed. BSCA may be formed to the backside portion of the source drain. A backside power rail (BPR) may be formed in another inter-layer dielectric and a backside power delivery network (hereinafter “BSPDN”) may be formed.

Advantages of the present invention include a larger CD of a backside portion of a source drain compared to a CD of a frontside portion of the source drain, increasing an overlap contact area for a BSCA to the backside portion of the source drain, improving reliability of the BSCA.

The present invention relates, generally, to the field of semiconductor manufacturing, and more particularly a backside contact.

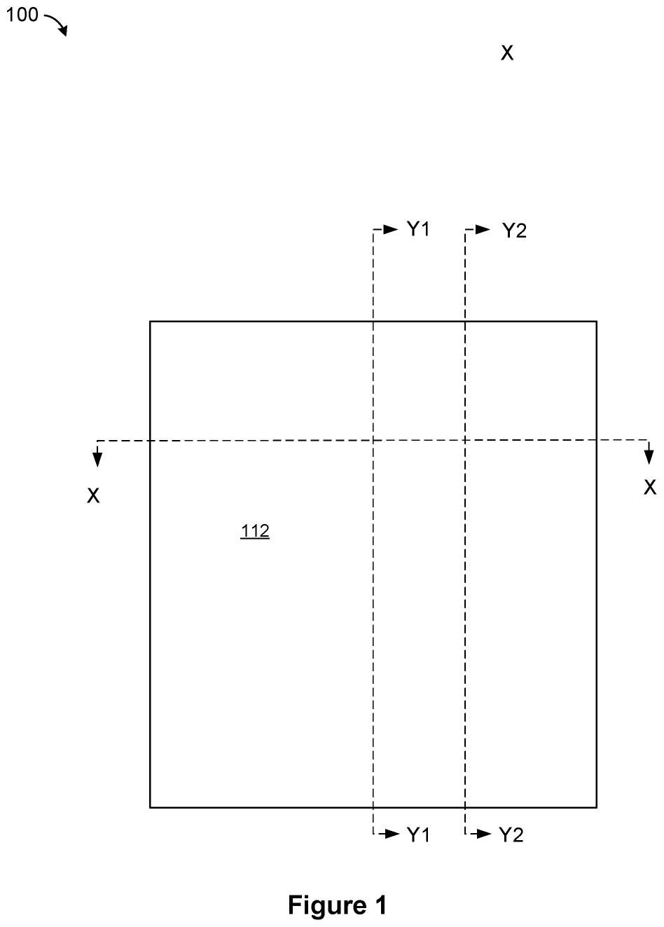

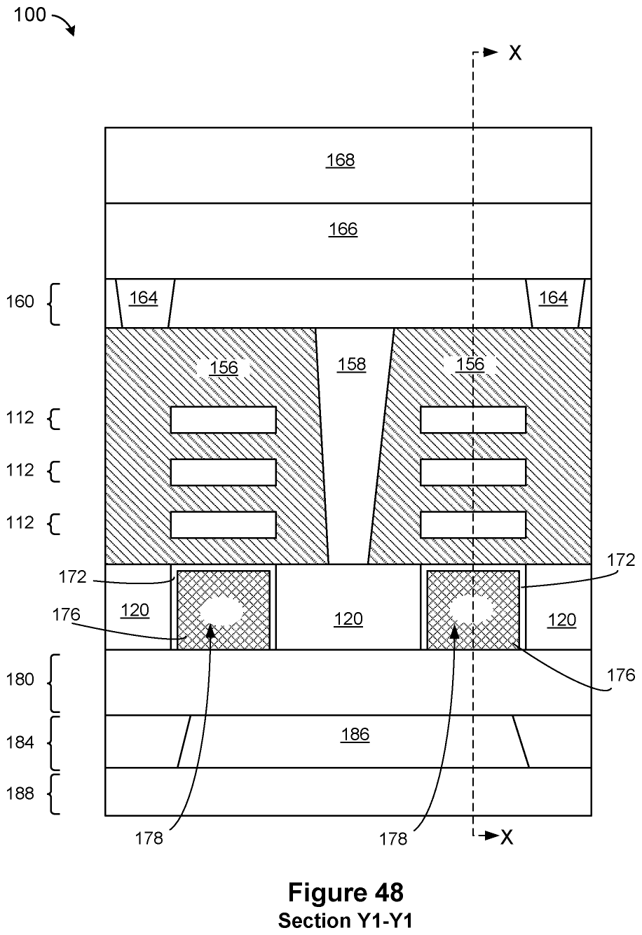

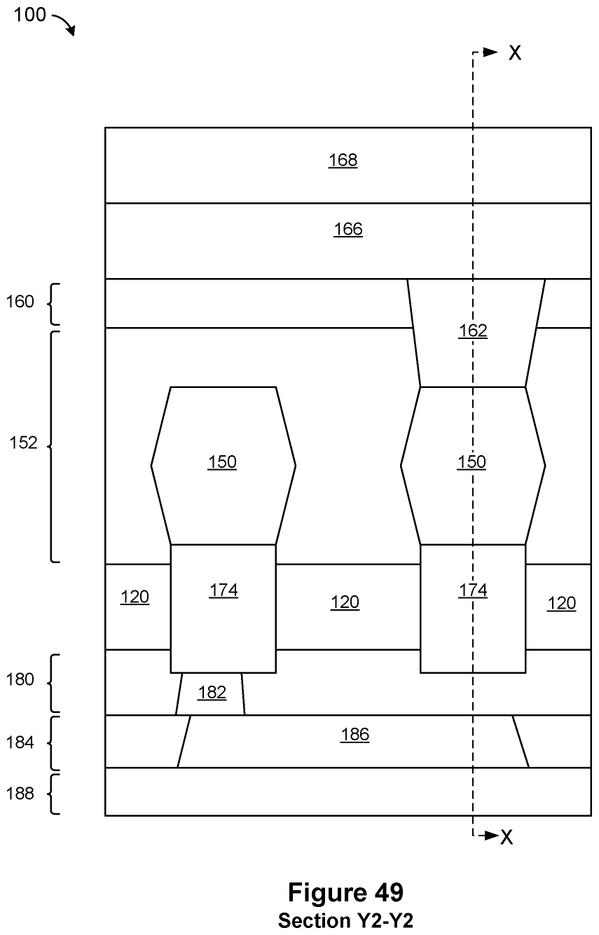

Embodiments of the present invention disclose a structure and a method of forming a FET nanosheet with a self-aligned backside trench epitaxy for low contact resistivity are described in detail below by referring to the accompanying drawings in FIGS. 1-49, in accordance with an illustrative embodiment.

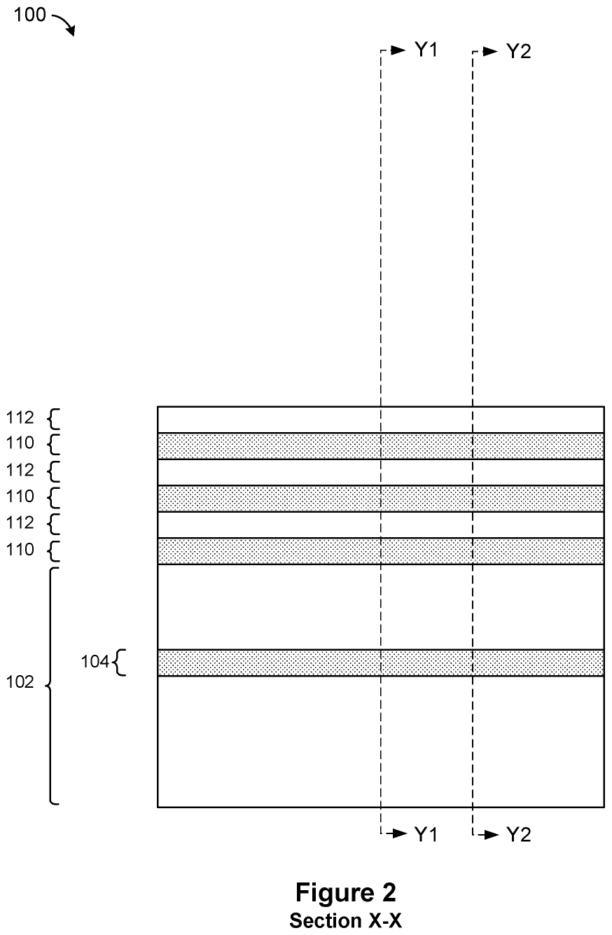

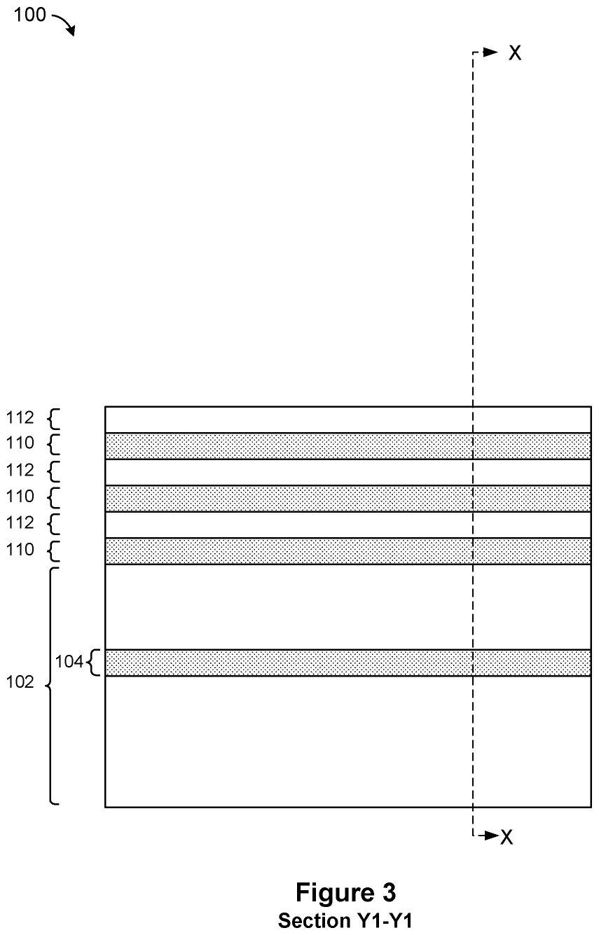

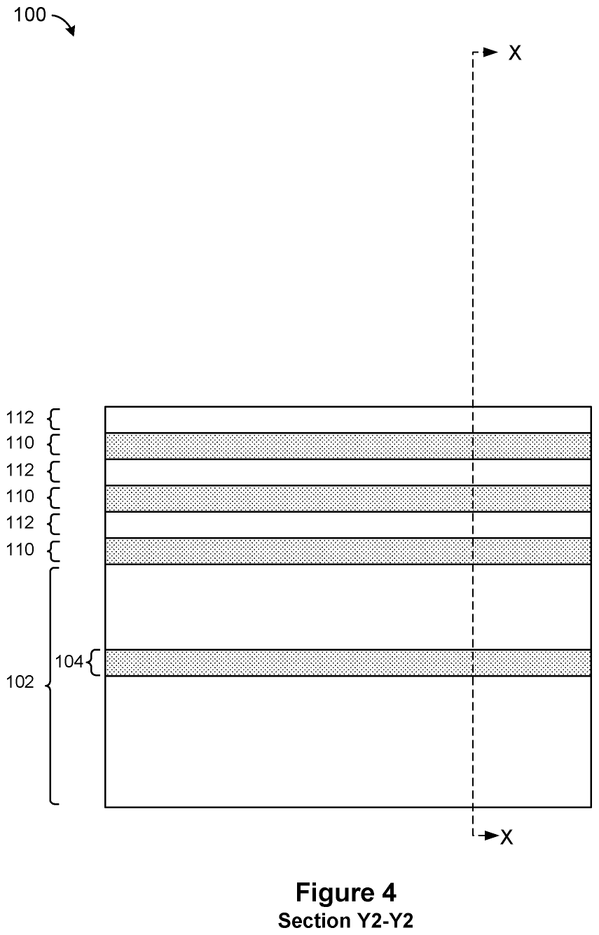

Referring now to FIGS. 1, 2, 3 and 4, a semiconductor structure 100 (hereinafter “structure”) at an intermediate stage of fabrication is shown according to an exemplary embodiment. FIG. 1 is a top view of the structure 100. FIG. 2 is a cross-sectional view of the structure 100 along section line X-X. FIGS. 3 and 4 are each a cross-sectional view of the structure 100 along section lines Y1-Y1 and Y2-Y2, respectively. FIGS. 3 and 4 are each perpendicular to section line X-X. The structure 100 of FIG. 1 may be formed or provided.

The structure 100 may include alternating layers of sacrificial semiconductor material and semiconductor channel material stacked one on top of another on a substrate. It should be noted that, while a limited number of alternating layers are depicted, any number of alternating layers may be formed.

The substrate may be a substrate which includes a silicon substrate 102 and an etch stop layer 104 in the silicon substrate 102. In other embodiments, the substrate may be, for example, a bulk substrate, which may be made from any of several known semiconductor materials such as, for example, silicon, germanium, silicon-germanium alloy, and compound (e.g. III-V and II-VI) semiconductor materials. Non-limiting examples of compound semiconductor materials include gallium arsenide, indium arsenide, and indium phosphide, or indium gallium arsenide. Typically, the substrate may be approximately, but is not limited to, several hundred microns thick.

The etch stop layer 104, may, for example, be silicon germanium with a germanium concentration about 25 atomic percent, although percentages greater than 25 percent and less than 25 percent may be used. The etch stop layer 104 can be formed using an epitaxial SiGe growth from the Si substrate.

The substrate 102 which includes the etch stop layer 104 has a key benefit compared to a substrate 102 with a high germanium percentage silicon germanium epitaxy layer as etch stop layer. The substrate 102 with the etch stop layer 104 has a lower risk of having defects due to the lower percentage of germanium of about 25 atomic percent and thickness of the etch stop layer 104 is also less than a critical thickness.

The alternating layers of sacrificial semiconductor material and semiconductor channel material may include a sacrificial semiconductor material layer 110 (hereinafter “sacrificial layer”), covered by a semiconductor channel material layer 112 (hereinafter “channel layer”), covered by a sacrificial layer 110, covered by a channel layer 112, covered by a sacrificial layer 110, covered by a channel layer 112.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition technique, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth techniques include, for example, rapid thermal chemical vapor deposition (RTCVD), low-energy plasma deposition (LEPD), ultra-high vacuum chemical vapor deposition (UHVCVD), low pressure chemical vapor deposition (LPCVD), atmospheric pressure chemical vapor deposition (APCVD) and molecular beam epitaxy (MBE). The temperature for epitaxial deposition typically ranges from approximately 550° C. to approximately 900° C. Although higher temperature typically results in faster deposition, the faster deposition may result in crystal defects and film cracking. The epitaxial growth the first and second semiconductor materials that provide the sacrificial semiconductor material layers and the semiconductor channel material layers, respectively, can be performed utilizing any well-known precursor gas or gas mixture. Carrier gases like hydrogen, nitrogen, helium and argon can be used.

Each sacrificial layer 110 is composed of a first semiconductor material which differs in composition from at least an upper portion of the substrate 102 and the channel layer 112. In an embodiment, each sacrificial layer 110 may be a silicon-germanium semiconductor alloy and have a germanium concentration less than 50 atomic percent. In another example, each sacrificial layer 110 may have a germanium concentration ranging from about 20 atomic percent to about 40 atomic percent. Each sacrificial layer 110 can be formed using known deposition techniques or an epitaxial growth technique as described above.

Each channel layer 112 is composed of a second semiconductor material which differs in composition from at least the upper portion of the substrate 102 and the sacrificial layer 110. Each channel layer 112 has a different etch rate than the first semiconductor material of sacrificial layer 110. The second semiconductor material can be, for example, silicon. The second semiconductor material, for each channel layer 112 can be formed using known deposition techniques or an epitaxial growth technique as described above.

The alternating layers of sacrificial layer 110 and channel layer 112 can be formed by sequential epitaxial growth of alternating layers of the first semiconductor material and the second semiconductor material.

The sacrificial layers 110 may have a thickness ranging from about 5 nm to about 15 nm, and the channel layers 112 may have a thickness ranging from about 4 nm to about 12 nm. Each sacrificial layer 110 may have a thickness that is the same as, or different from, a thickness of each channel layer 112. In an embodiment, each sacrificial layer 110 has an identical thickness. In an embodiment, each channel layer 112 has an identical thickness. The stack sacrificial layer 108 may each have a thickness ranging from about 5 nm to about 12 nm.

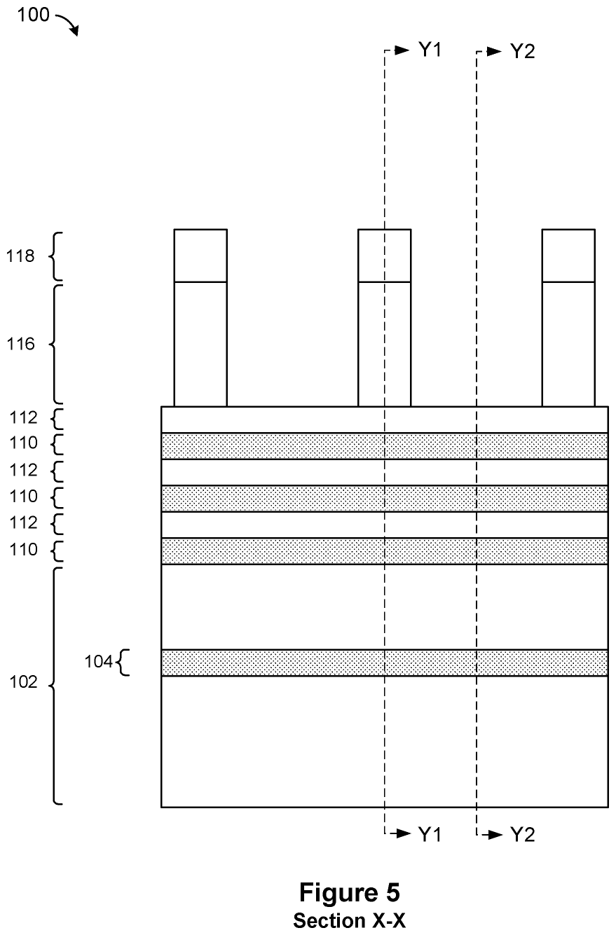

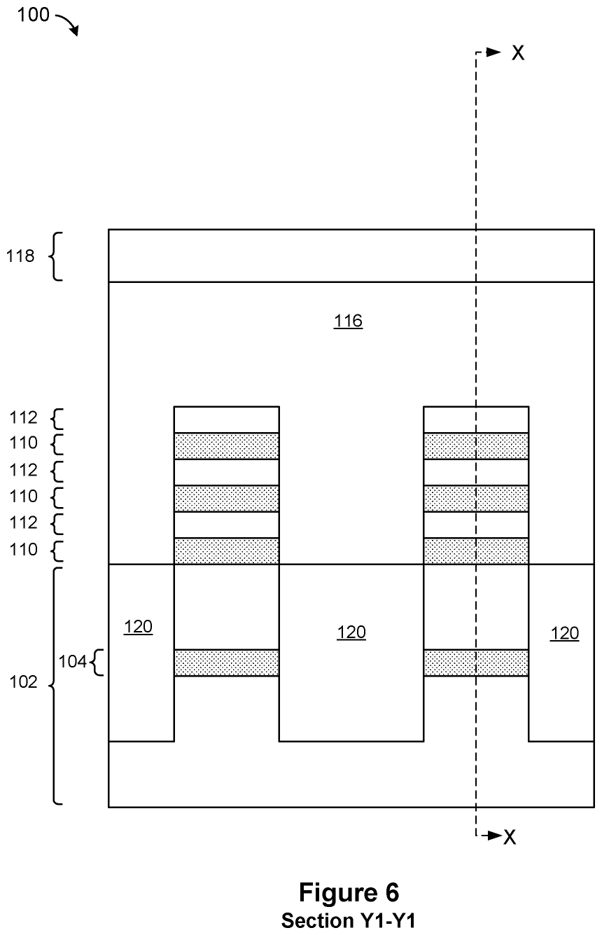

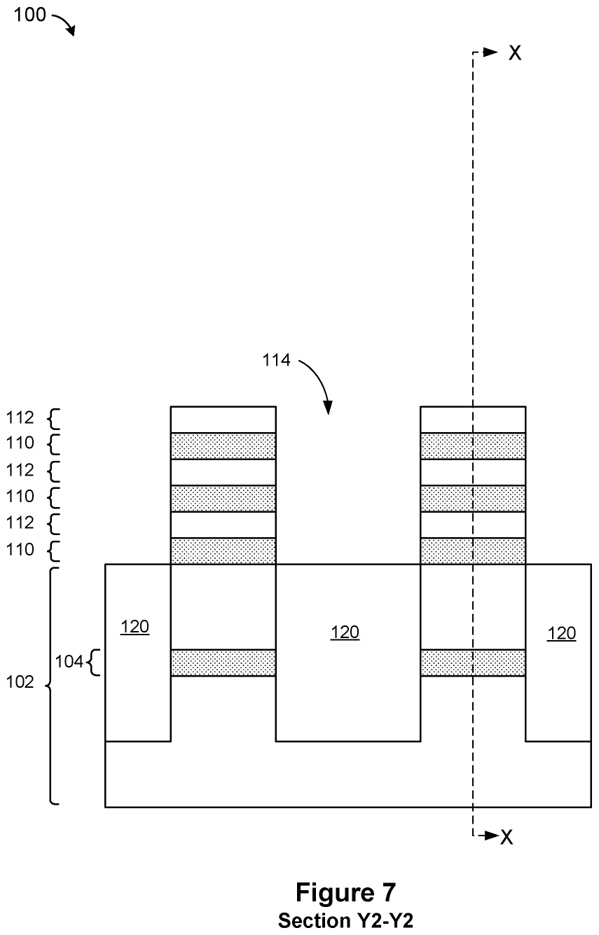

Referring now to FIGS. 5, 6 and 7, the structure 100 is shown according to an exemplary embodiment. FIGS. 5, 6 and 7 are each a cross-sectional view of the structure 100 along section lines X-X. Y1-Y1 and Y2-Y2, respectively. FIGS. 6 and 7 are perpendicular to FIG. 5. A trench 114 may be formed. A shallow trench isolation region (hereinafter “STI”) 120 may be formed in the trench 114. A sacrificial gate 116 and a gate cap 118 may be formed.

The alternating layers of sacrificial layers 110 and channel layers 112 may be formed into fins, by methods known in the art. The fins may have a length perpendicular to section lines Y1-Y1 and Y2-Y2, and parallel to section line X-X. The fins may be formed by methods known in the arts, and include steps such as forming a hard mask, on the alternating layers, patterning the hard mask, and subsequent formation of one or more trenches 114, by removal of portions of each layer of the stacked nanosheet. The trench 114 may form the nanosheet stack into fins by an anisotropic etching technique, such as, for example, reactive ion etching (RIE), and stopping on etching a portion of the substrate 102 between each nanosheet stack.

The STI 120 may be formed between adjacent nanosheet stacks in the portion of the trench 114, between adjacent nanosheet stacks. The STI 120 may be a dielectric material and may be between adjacent nanosheet stacks and formed using known deposition, planarization and etching techniques. Adjacent nanosheet stacks are isolated from one another in the substrate 102 by the STI 120. A lower horizontal surface and a portion of a vertical side surface of the STI 120 may be adjacent to a lower horizontal surface and a vertical side surface of the substrate 102. The lower horizontal surface of the STI 120 may be below a lower horizontal surface of the etch stop layer 104. The STI 120 may provide physical and electrical isolation between adjacent nanosheet stacks.

Each fin of nanosheet stack may include a sacrificial layer 110, covered by a channel layer 112, covered by a sacrificial layer 110, covered by a channel layer 112, covered by a sacrificial layer 110, covered by a channel layer 112. By way of illustration, two fins are depicted in the drawings of the present application, although any number of fins may be formed.

The material stacks that can be employed in embodiments of the present invention are not limited to the specific embodiment illustrated in FIGS. 5-7. In FIGS. 5-7, and only by way of an example, the nanosheet stack includes three layers of sacrificial layers 110 alternating with three channel layers 112. The nanosheet stack can include any number of sacrificial layers 110 and channel layers 112. The nanosheet stack is used to produce a gate all around device that includes vertically stacked semiconductor channel material nanosheets for a p-FET or an n-FET.

The sacrificial gate 116 and the gate cap 118 are formed orthogonal (perpendicular) to the fins. By way of illustration, three sacrificial gates 116 are depicted in the drawings of the present application, although any number of sacrificial gates 116 may be formed. The sacrificial gate 116 may include a single sacrificial material or a stack of two or more sacrificial materials. The at least one sacrificial material can be formed by forming a blanket layer (or layers) of a material (or various materials) and then patterning the material (or various materials) by lithography and an etch. The sacrificial gate 116 can include any material including, for example, polysilicon, amorphous silicon, or multilayered combinations thereof. In an embodiment where amorphous silicon is used as a material for the sacrificial gate 116, a thin layer of SiO2 is deposited first to separate the nanosheet stack from the amorphous silicon. The sacrificial gate 116 can be formed using any deposition technique including, for example, chemical vapor deposition (CVD), physical vapor deposition (PVD), high density plasma (HDP) deposition, and spin on techniques. Optionally, the gate cap 118 may be formed as part of the sacrificial gate 116 in accordance with known techniques.

In an embodiment, the sacrificial gate 116 is deposited with a thickness sufficient to fill, or substantially fill, the spaces between adjacent nanosheet structures and cover a horizontal upper surface of the uppermost channel layer 112 of the nanosheet stack. The sacrificial gate 116 may be adjacent to vertical side surfaces of the nanosheet stack or fins. The sacrificial gate 116 may cover an upper horizontal surface of the STI 120 between adjacent nanosheet stacks. A height of the sacrificial gate 116 may be much thicker than the underlying structure and may have a height between 100 nm and 150 nm about the nanosheet stack. The gate cap 118 may cover an upper horizontal surface of the sacrificial gate 116. Gate patterning may be performed by conventional lithography and etch process, such that portions of the gate cap 118 and portions of the sacrificial gate 116 are removed from a subsequently formed source drain region.

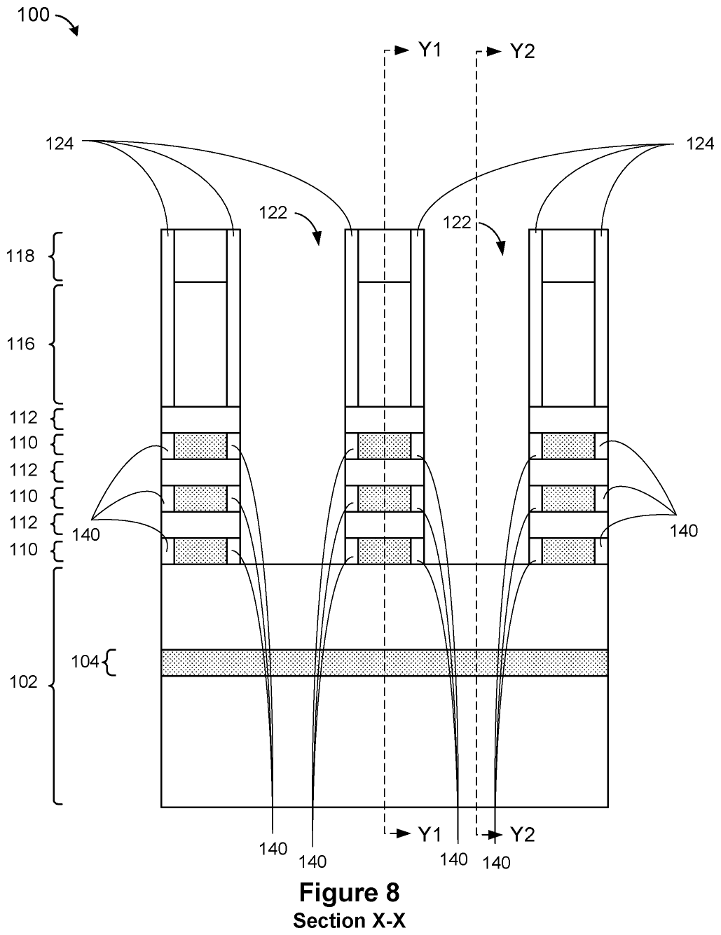

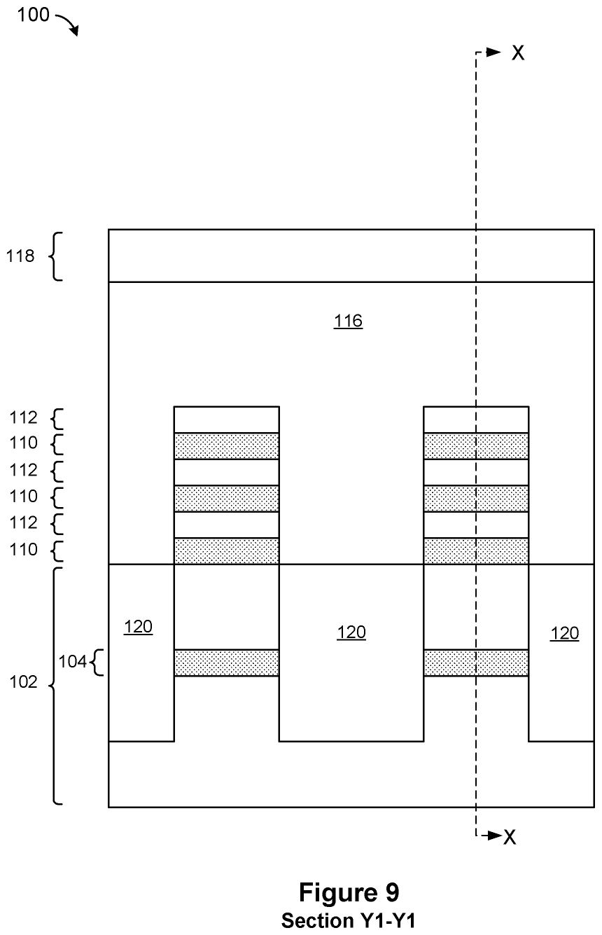

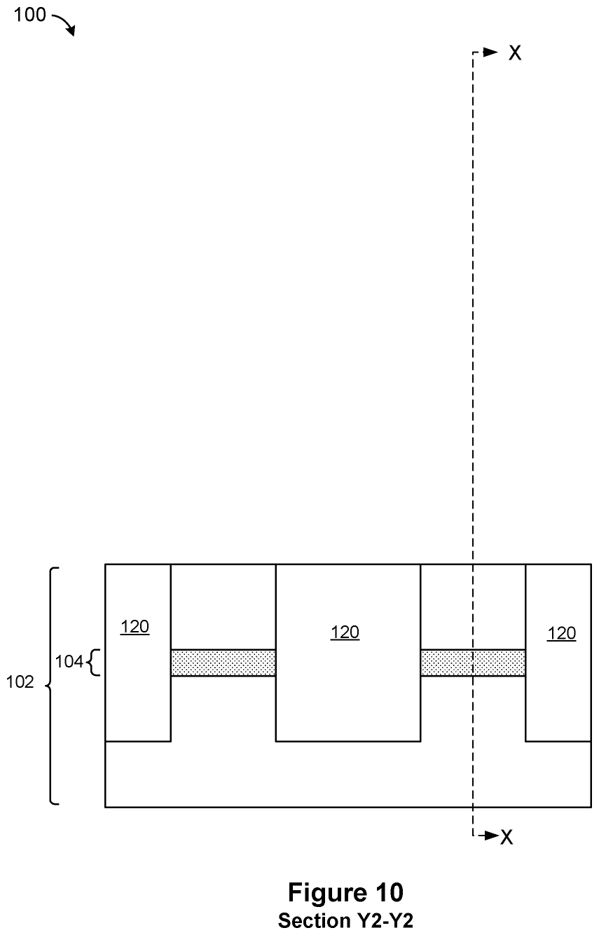

Referring now to FIGS. 8, 9 and 10, the structure 100 is shown according to an exemplary embodiment. FIGS. 8, 9 and 10 are each a cross-sectional view of the structure 100 along section lines X-X, Y1-Y1 and Y2-Y2, respectively. FIGS. 9 and 10 are perpendicular to FIG. 8. FIG. 9 is the same as FIG. 6. A gate spacer 124 may be formed. A source drain trench 122 may be formed. An inner spacer 140 may be formed.

Portions of the fins may be removed, selective to the sacrificial gate 116, the gate cap 118 and the gate spacer 124, exposing an upper horizontal surface of the substrate 102, forming the source drain trench 122. Portions of the sacrificial layer 110 may be removed and an inner spacer 140 may be formed where the portion of the sacrificial layer 110 were removed.

The gate spacer 124 may be formed on vertical side surfaces of the sacrificial gate 116 and the gate cap 118. The gate spacer 124 may be formed by conformally depositing a dielectric material, followed by a combination of dry and wet anisotropic etch and recessing steps. The gate spacer 124 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by an anisotropic vertical etch process such as a reactive ion etch (RIE), or any suitable etch process. The gate spacer 124 may include any dielectric material such as silicon nitride (SiN), silicon boron carbon nitride (SiBCN), silicon oxide carbon nitride (SiOCN), aluminum oxide (AlOx), and may include a single layer or may include multiple layers of dielectric material.

The alternating layers of sacrificial layers 110 and channel layers 112 may be formed into nanosheet stacks, by methods known in the art. The vertical portion of the nanosheet stack which is recessed may be between two adjacent sacrificial gates 116, gate cap 118 and the gate spacers 124 surrounding each sacrificial gate 116. The vertical portion of the nanosheet stack which is recessed may include removing a vertical portion of the nanosheet stack, including removal of aligned vertical portions of each of the channel layers 112 and each of the sacrificial layers 110. The sacrificial gate 116, gate cap 118 and the gate spacers 124 may protect remaining portions of the nanosheet stack. The vertical portion of the nanosheet stack may be recessed via etching using an anisotropic etching technique, such as, for example, reactive ion etching (RIE), and stopping at the substrate 102. There may be any number of vertical portions removed in the structure 100, between sacrificial gates 116. The vertical portion of the nanosheet stack may be recessed to form the source drain trench 122 for subsequent formation of a source drain epitaxy. The source drain trench 122 may have a length perpendicular to section line X-X and parallel to sections line Y1-Y1 and Y2-Y2, and perpendicular to the fins.

Each nanosheet stack may include a sacrificial layer 110, covered by a channel layer 112, covered by a sacrificial layer 110, covered by a channel layer 112, covered by a sacrificial layer 110, covered by a channel layer 112. Above the nanosheet stack is the sacrificial gate 116 and the gate cap 118, with the dielectric spacer 124 on opposite vertical sides. The nanosheet stack may be vertically aligned with the gate spacer 124 surrounding the sacrificial gate 116 and the gate cap 118.

The inner spacer 140 may be formed on either side of the sacrificial layer 110 where the vertical portions of the sacrificial layer 110 were removed. A portion of each of the sacrificial layers 110 on either side of where the source drain trench 122, may be indented. The portion of each of the sacrificial layers 110 may be indented selective to the sacrificial gate 116, the gate cap 118, the gate spacer 124, the channel layers 112, the substrate 102 and the STI 1202.

The inner spacer 140 may be formed on either side of the sacrificial layers 110. Outer vertical sides of the inner spacer 140 may vertically align with the channel layers 112 and inner vertical sides of the inner spacer may vertically align with remaining portions of the sacrificial layers 110.

The inner spacer 140 may each be formed after several processes, including for example, conformally depositing or growing a dielectric and performing an isotropic etch process. The inner spacer 140 may include any dielectric material such as silicon nitride and may include a single layer or may include multiple layers of dielectric material.

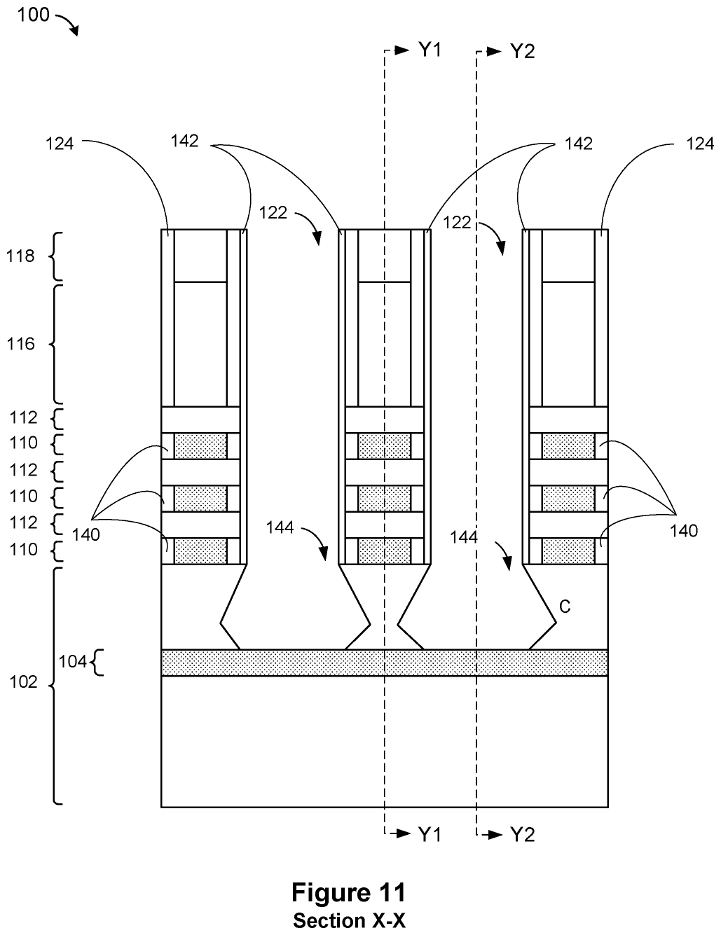

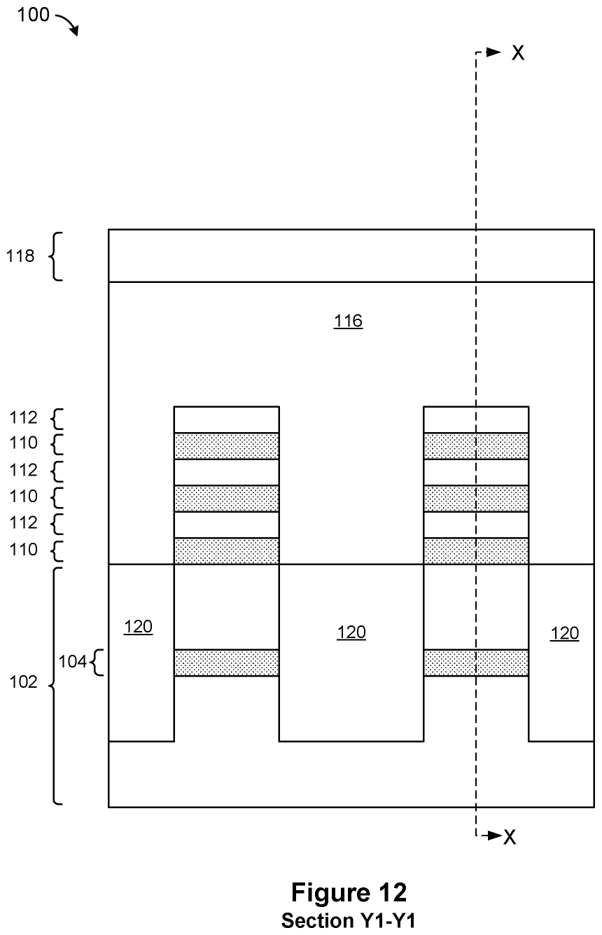

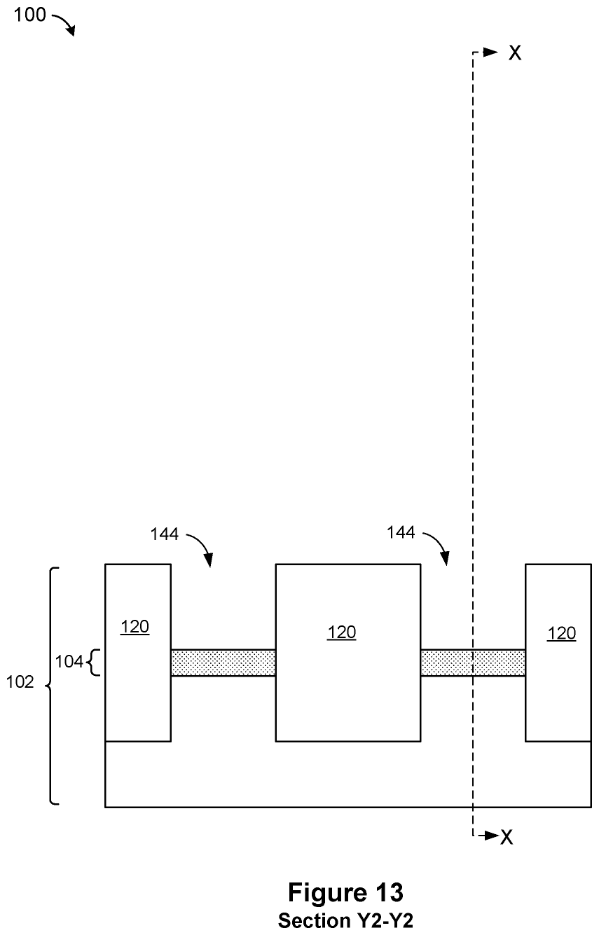

Referring now to FIGS. 11, 12 and 13, the structure 100 is shown according to an exemplary embodiment. FIGS. 11, 12 and 13 are each a cross-sectional view of the structure 100 along section lines X-X, Y1-Y1 and Y2-Y2, respectively. FIGS. 12 and 13 are perpendicular to FIG. 11. FIG. 12 is the same as FIGS. 6 and 9. A protective liner 142 may be formed on vertical side surfaces of the source drain trench 122. A trench 144 may be formed.

The protective liner 142 may be formed on vertical side surfaces of the channel layers 112, the inner spacer 140 and the gate spacer 124, providing protection during subsequent processing steps. The protective liner 142 may be formed after several processes, including for example, conformally depositing or growing a dielectric and performing an isotropic etch process. The protective liner 142 may include any dielectric material such as silicon nitride and may include a single layer or may include multiple layers of dielectric material. The protective liner 142 may be 2.5 nm thick, although a thickness less than or greater than 2.5 nm may be acceptable.

The trench 144 may be formed by removal of a portion of the substrate 102 at a lower horizontal surface of the source drain trench 122. The trench 144 may be formed by removing a vertical portion and a horizontal portion of the substrate 102, from a lower horizontal surface of the source drain trench 122. The trench 144 may be formed by a combination of wet/dry etch using known processes. The trench 144 may have a portion below the nanosheet stack, which is wider than the source drain trench 122. The trench 144 may be referred to as a sigma silicon etch due to a shape with a vertical side surface which has an outward slope and then an inward slope when transferring from an upper horizontal surface of the substrate 102 to a lower horizontal surface of the substrate 102. The etch stop layer 104 helps prevent the trench 144 from extending further into the substrate 102 and provides a lower horizontal boundary of the trench 144. The trench 144 may have a length perpendicular to section line X-X and parallel to sections line Y1-Y1 and Y2-Y2.

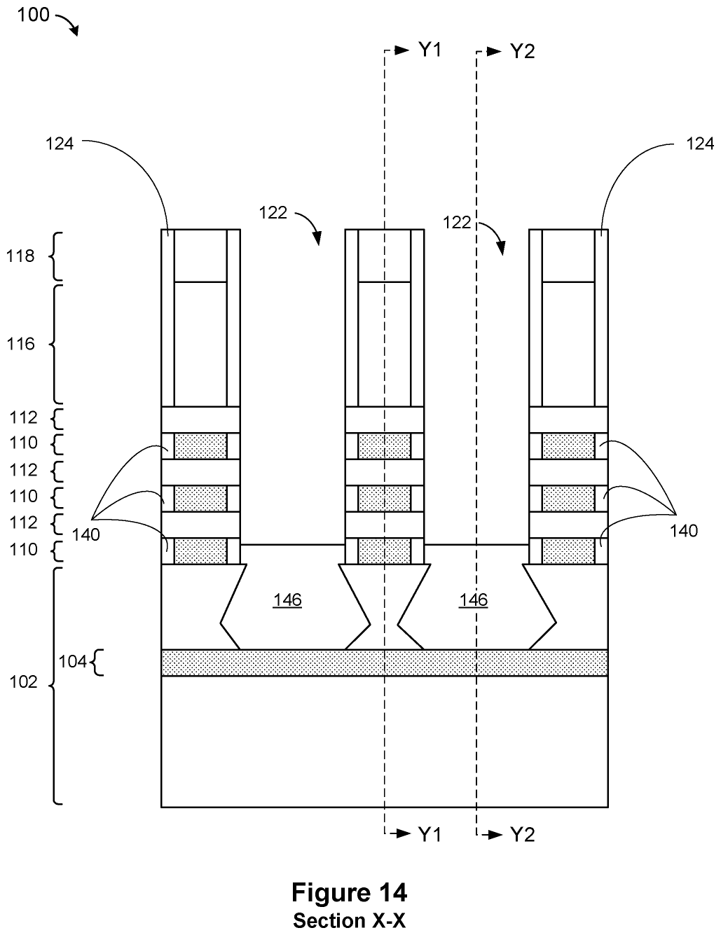

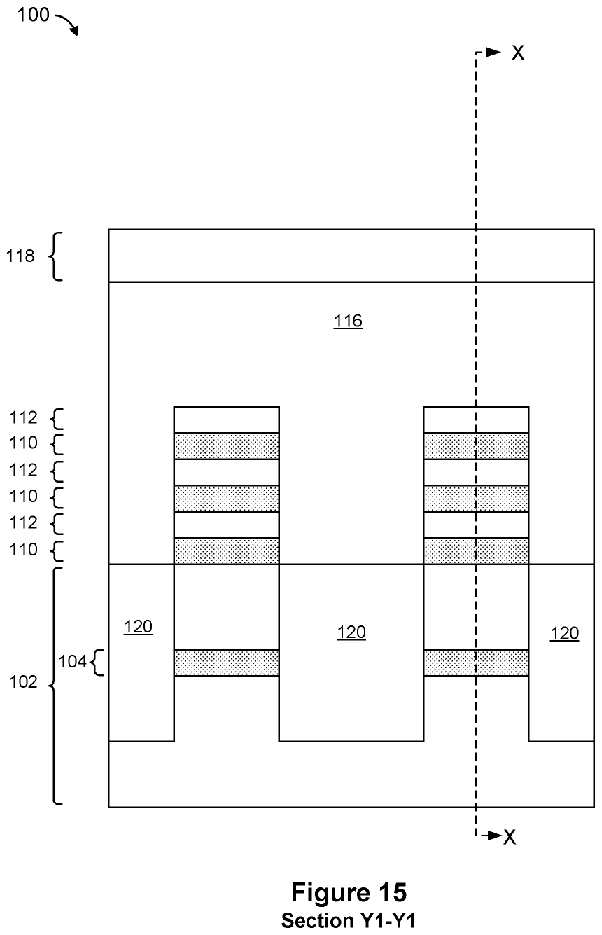

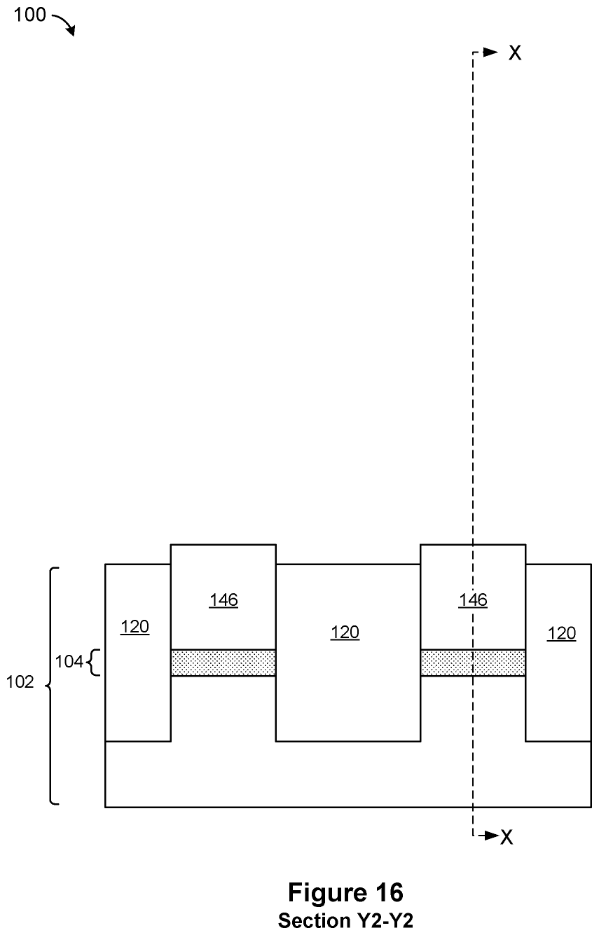

Referring now to FIGS. 14, 15 and 16, the structure 100 is shown according to an exemplary embodiment. FIGS. 14, 15 and 16 are each a cross-sectional view of the structure 100 along section lines X-X, Y1-Y1 and Y2-Y2, respectively. FIGS. 15 and 16 are perpendicular to FIG. 14. FIG. 15 is the same as FIGS. 6, 9 and 12. A placeholder 146 may be formed. The protective liner 142 may be removed.

The placeholder 146 may be formed in the trench 144 and in a portion of the source drain trench 122. The placeholder 146 may be formed by depositing a sacrificial material, followed by a combination of dry and wet isotropic etch and recessing steps, or placeholder 146 may be formed by selectively epitaxial growth of a semiconductor material, such as SiGe or III-V epi. In an embodiment, the placeholder 146 may include one or more layers. In an embodiment, the placeholder 146 may include material such as, silicon germanium, SiN/SiO2, TiOx, AlOx, or any combination of these materials.

The protective liner 142 may be removed by known techniques, including for example an anisotropic etching technique, such as, for example, reactive ion etching (RIE).

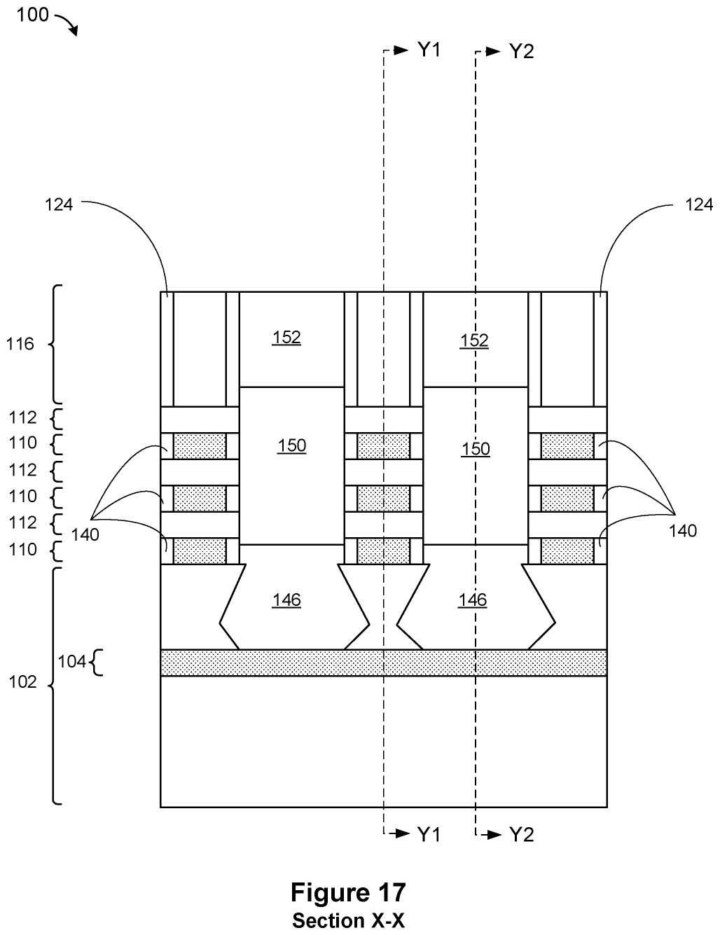

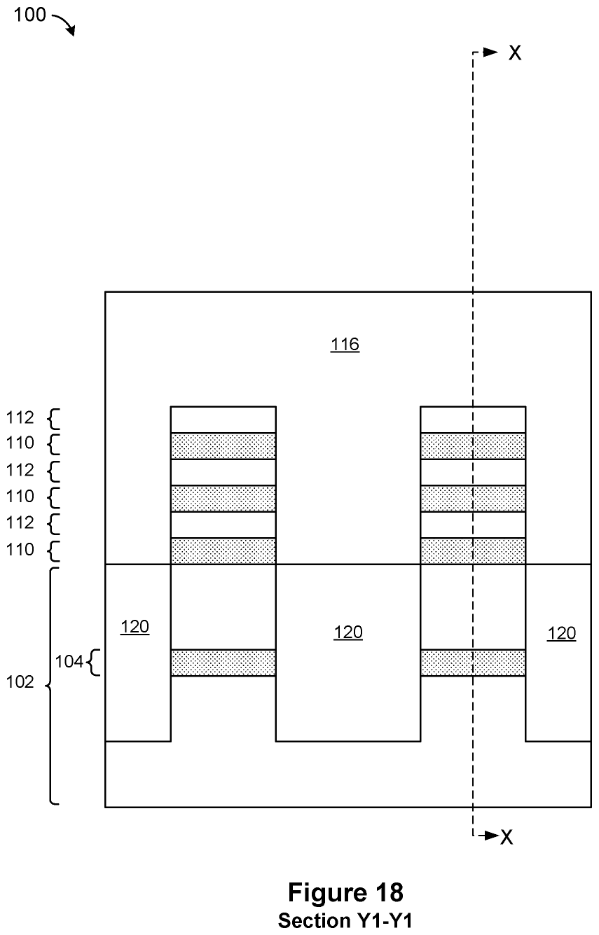

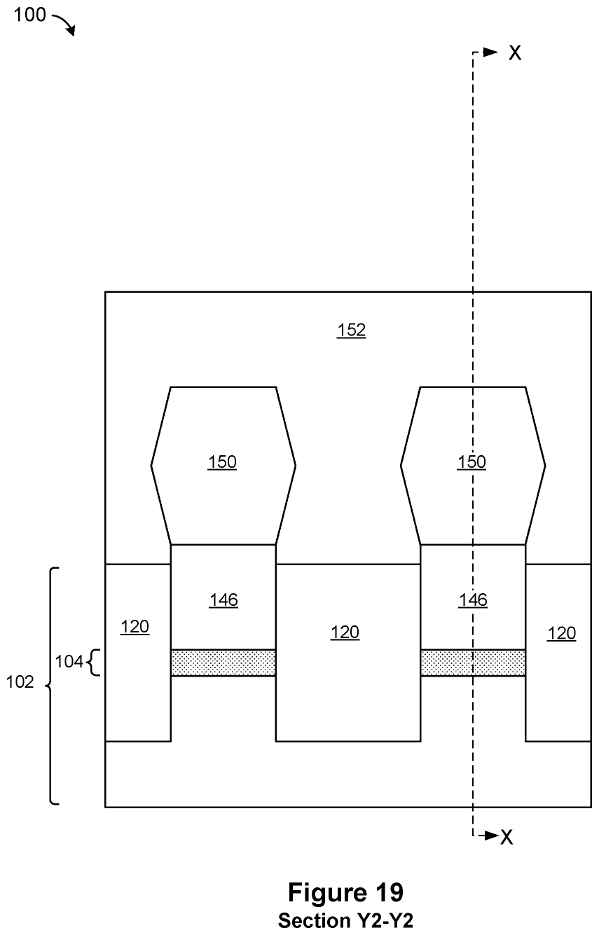

Referring now to FIGS. 17, 18 and 19, the structure 100 is shown according to an exemplary embodiment. FIGS. 17, 18 and 19 are each a cross-sectional view of the structure 100 along section lines X-X, Y1-Y1 and Y2-Y2, respectively. FIGS. 18 and 19 are perpendicular to FIG. 17. A frontside portion of a source drain 150 and an inter-layer dielectric (hereinafter “ILD”) 152 may be formed.

The frontside portion of the frontside portion of the source drain 150 may be epitaxially grown surrounding a vertical portion of the nanosheet stack on opposite sides of the sacrificial gate 116. A lower surface of the frontside portion of the frontside portion of the source drain 150 may be adjacent to an upper surface of the placeholder 146. A vertical side surface of the frontside portion of the source drain 150 may be adjacent to vertical side surfaces of the inner spacer 140 and the channel layers 112. An upper surface of the frontside portion of the source drain 150 may be a greater distance from the substrate 102 than an upper surface of the uppermost channel layer 112.

The ILD 152 may be formed by conformally depositing or growing a dielectric material, followed by a CMP or etch steps. The ILD 152 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the ILD 152 may include one or more layers. In an embodiment, the ILD 152 may include any dielectric material such as silicon oxide, silicon oxynitride, silicon nitride, SiBCN, SiOC, low-k dielectric or any combination of these materials. A lower surface of the ILD 152 may be adjacent to an upper surface of the frontside portion of the source drain 150. A vertical side surface of the ILD 148 may be adjacent to a vertical side surface of the gate spacer 124. A vertical side surface of the ILD 152 may be adjacent to a vertical side surface of the frontside portion of the source drain 150.

A chemical mechanical polishing (CMP) technique may be used to remove excess material and polish upper surfaces of the structure 100, removing the gate cap 118 and exposing an upper horizontal surface of the sacrificial gate 116. An upper surface of the structure 100 may also include upper horizontal surfaces of the ILD 152 and the gate spacer 124.

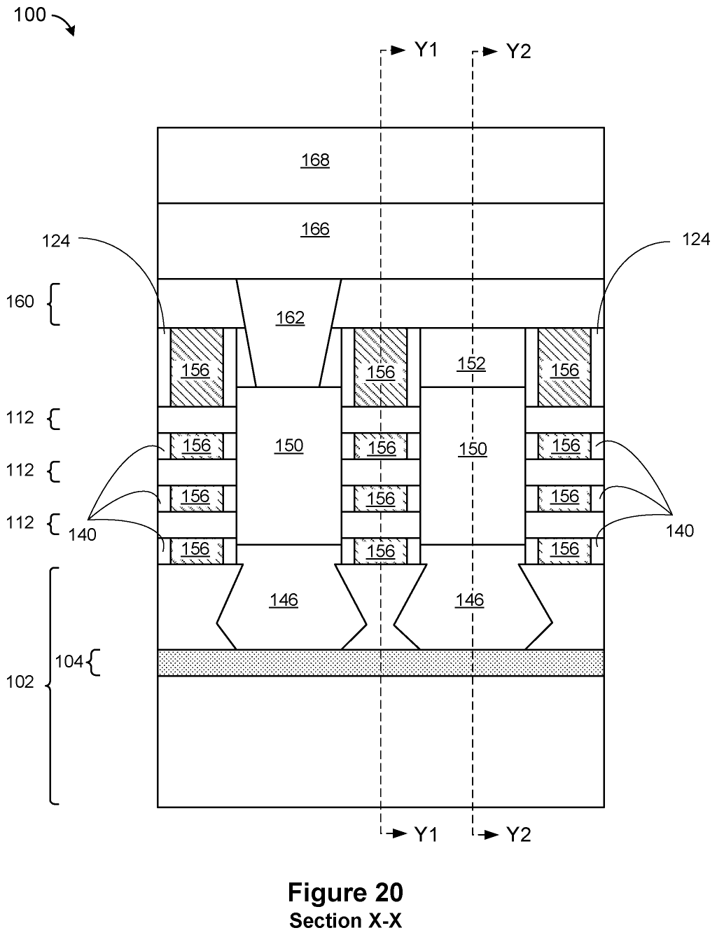

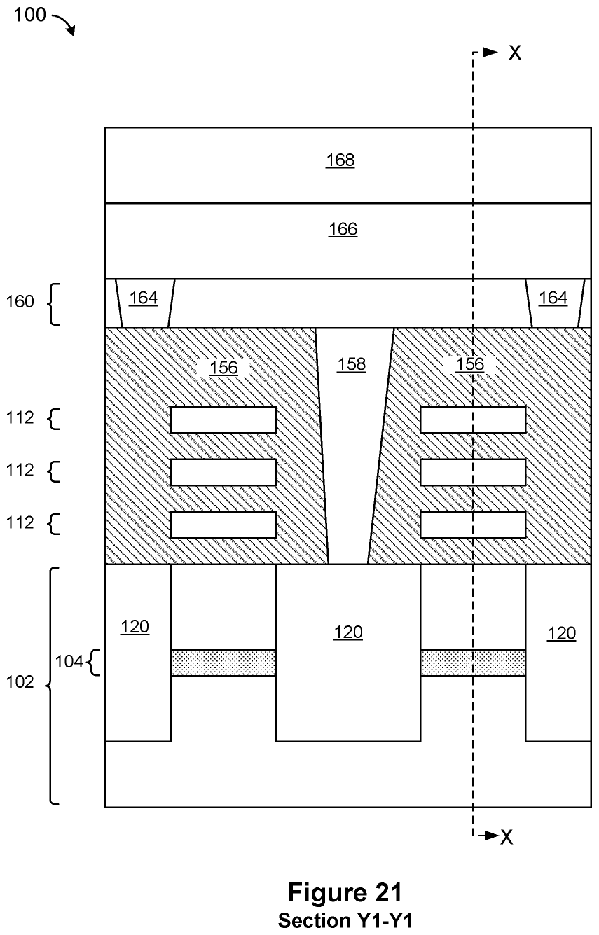

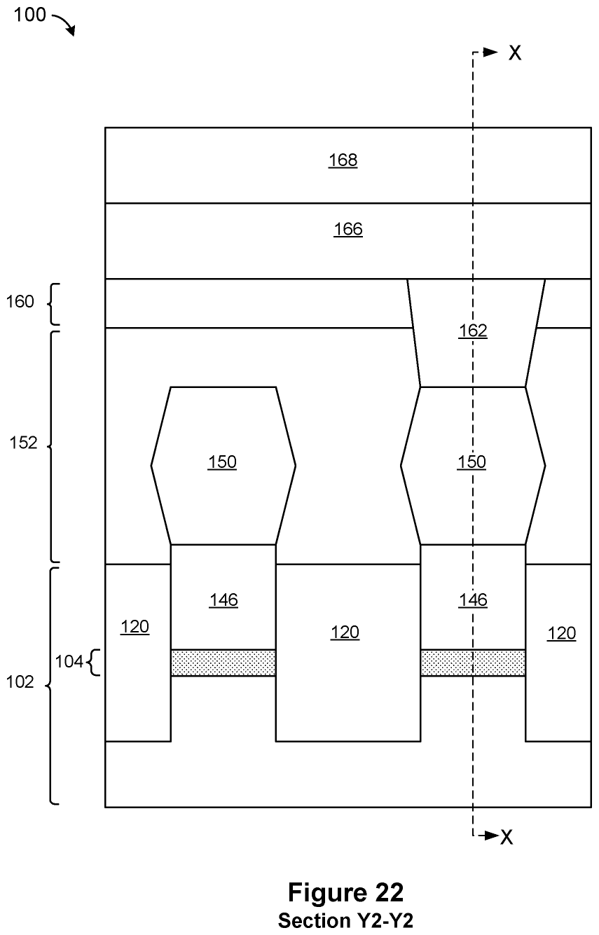

Referring now to FIGS. 20, 21 and 22, the structure 100 is shown according to an exemplary embodiment. FIGS. 20, 21 and 22 are each a cross-sectional view of the structure 100 along section lines X-X, Y1-Y1 and Y2-Y2, respectively. FIGS. 21 and 22 are perpendicular to FIG. 20. A gate cut dielectric 158 may be formed. The sacrificial gate 116 and the sacrificial layers 110 may be removed. A replacement gate 156 may be formed. An inter-layer dielectric (hereinafter “ILD”) 160 may be formed. A contact 162 and a contact 164 may be formed. Back end of line (hereinafter “BEOL”) layers 166 (hereinafter “BEOL”) may be formed. A carrier wafer 168 may be bonded to the structure 100.

A gate cut opening (not shown) may be formed using methods known in the arts. For example, a lithograph patterning and dry etch technique may be used to selectively remove vertically aligned portions of the sacrificial gate 116 and the STI 120. The gate cut opening (not shown) may be formed parallel to the section X-X. The gate cut opening (not shown) may be between adjacent frontside portions of the frontside portion of the source drain 150. The gate cut opening (not shown) may be between adjacent nanosheet stacks.

The gate cut dielectric 158 may be formed in the gate cut opening (not shown). The gate cut dielectric 158 may be formed by conformally depositing or growing a dielectric material, filling the gate cut opening (not shown). The gate cut dielectric 158 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the gate cut dielectric 158 may include one or more layers. In an embodiment, the gate cut dielectric 158 may include any dielectric material such as silicon oxide, silicon oxynitride, silicon nitride, SiBCN, SiOC, low-k dielectric or any combination of these materials. A lower surface of the gate cut dielectric 158 may be adjacent to an upper surface of the STI 120. A vertical side surface of the gate cut dielectric 158 may be adjacent to vertical side surfaces of the replacement gate 116.

A chemical mechanical polishing (CMP) technique may be used to remove excess material and polish upper surfaces of the structure 100. An upper surface of the structure 100 may include horizontal surfaces of the ILD 152, the gate side spacers 124, the replacement gate 116 and the gate cut dielectric 158.

The sacrificial gate 116 and the sacrificial layers 110 may be removed by methods known in the arts. The sacrificial gate 116 and the sacrificial layers 110 are removed selective to the channel layers 112, the inner spacers 140, the ILD 152, the gate spacer 124, the frontside portion of the source drain 150, the placeholder 146, the gate cut dielectric 158 and the silicon substrate 102. For example, a dry etch process can be used to selectively remove the sacrificial layers 110, such as using vapor phased HCl dry etch. An upper surface and a lower surface of the channel layers 112 may be exposed. The sacrificial gate 116 and the sacrificial layers 110 may be removed simultaneously or sequentially.

The replacement gate 156 may be conformally formed on the structure 100, according to an exemplary embodiment. The replacement gate 156 is formed in each cavity of the nanosheet stack and surrounding suspended portions of the channel layers 112. The replacement gate 156 forms a layer surrounding exposed portions of the nanosheet stacks. The replacement gate 156 may cover exposed vertical side surfaces of one side of the side spacers 140 and exposed vertical surfaced of one side of the gate spacer 124. The replacement gate 156 may cover vertical side surfaces, an upper horizontal surface and a lower horizontal surface of the channel layers 110.

The replacement gate 156 may be deposited using typical deposition techniques, for example, atomic layer deposition (ALD), molecular layer deposition (MLD), and chemical vapor deposition (CVD). In an embodiment, the replacement gate 156 may include more than one layer, for example, a conformal layer of a high-k dielectric material such as HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. In an embodiment, a work function metal of a p-FET device may include a metal nitride, for example, titanium nitride or tantalum nitride, titanium carbide titanium aluminum carbide, or other suitable materials known in the art. In an embodiment, the work function metal of an n-FET device may include, for example, titanium aluminum carbide or other suitable materials known in the art. In an embodiment, the work function metal may include one or more layers to achieve desired device characteristics.

A chemical mechanical polishing (CMP) technique may be used to remove excess material and polish upper surfaces of the structure 100. An upper surface of the structure 100 may include an upper horizontal surface of the ILD 152, an upper horizontal surface of the gate spacer 124 and an upper horizontal surface of the replacement gate 156.

The ILD 160 may be conformally formed as described for the ILD 152. A lower horizontal surface of the ILD 160 may be adjacent to an upper horizontal surface of replacement gate 156, an upper horizontal surface of the gate spacer 124 and an upper horizontal surface of the ILD 152.

An opening (not shown) may be made in the structure 100 through the ILD 160 and the ILD 152 exposing an upper horizontal surface of the frontside portion of the source drain 150. A contact 162 may be formed in the opening (not shown) to form a contact to the frontside portion of the source drain 150. As shown in FIG. 20, there is 1 contact 162. A second opening (not shown) may be made through the ILD 160 to the replacement gate 156. A contact 164 may be made in the second opening (not shown) to form a contact to the replacement gate 156. As shown in FIG. 21 there are 2 contacts 164. There may be any number of contacts 162, 164 on the structure 100.

A chemical mechanical polishing (CMP) technique may be used to remove excess material and polish upper surfaces of the structure 100, exposing an upper horizontal surface of the ILD 160 and upper horizontal surfaces of the contacts 162, 164.

The BEOL layers 166 may be include layers of wiring and vias formed above the existing structure, above the contacts 162, 164 and the ILD 160. In an embodiment, the BEOL layers 166 may include 12 or more layers of metal lines and visas. The BEOL layers 166 may be formed using known techniques.

The carrier wafer 168 may be attached to an upper surface of the structure 100, mounted on an upper surface of the BEOL layers 166. The carrier wafer may be attached using conventional wafer bonding process, such as dielectric-to-dielectric bonding or copper-to-copper bonding process.

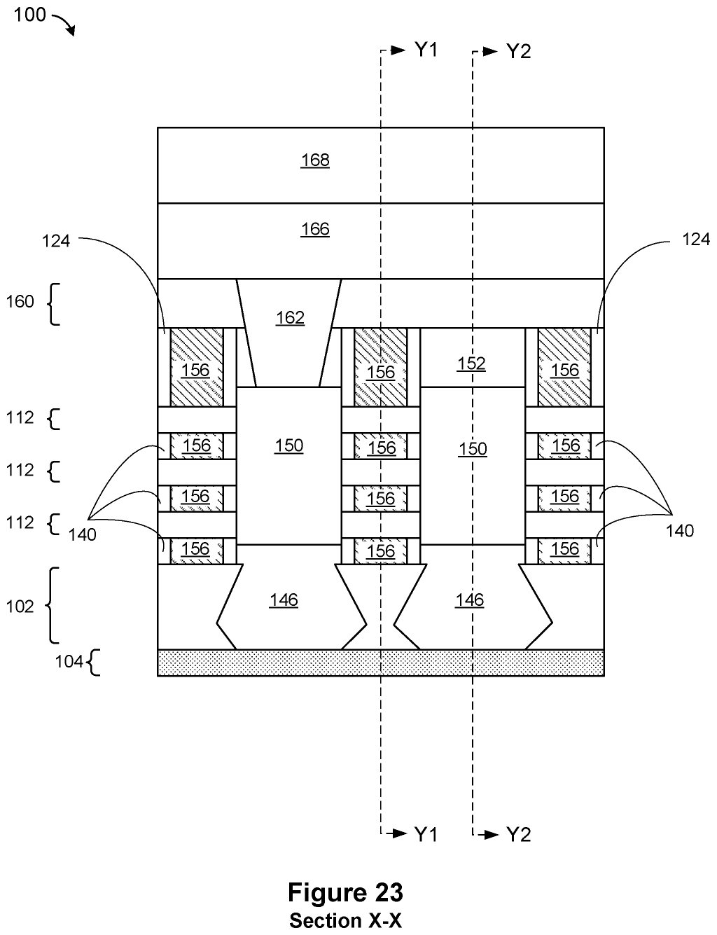

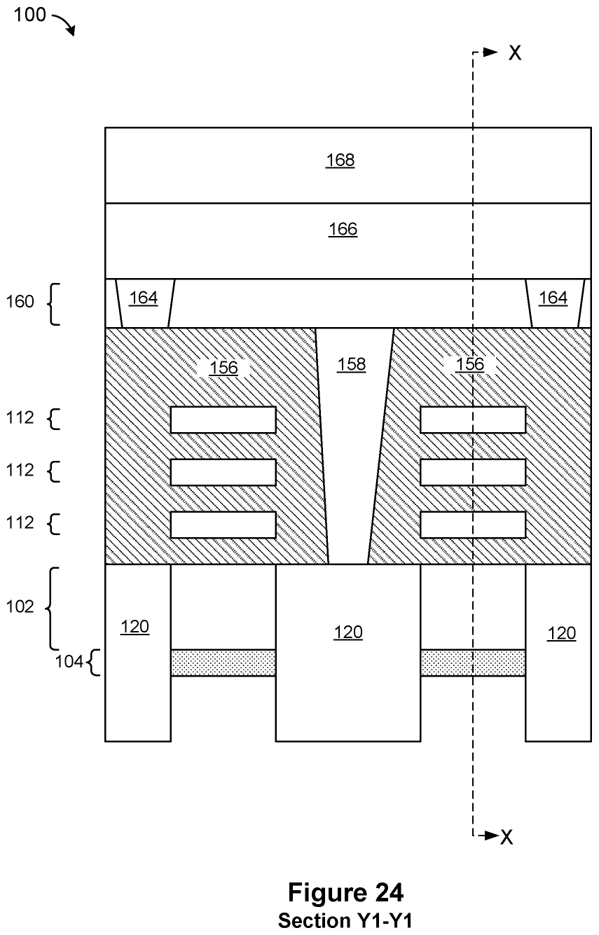

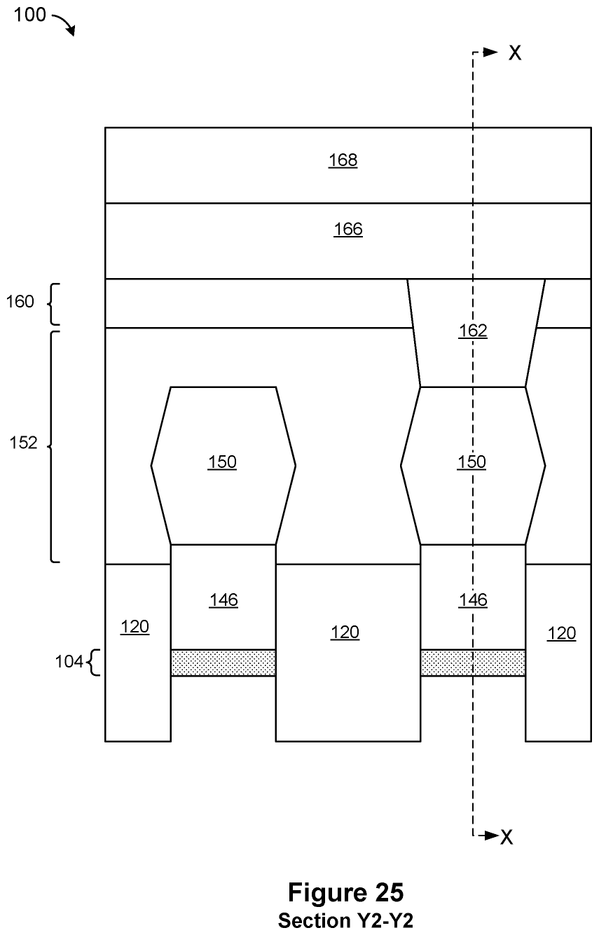

Referring now to FIGS. 23, 24 and 25, the structure 100 is shown according to an exemplary embodiment. FIGS. 23, 24 and 25 are each a cross-sectional view of the structure 100 along section lines X-X, Y1-Y1 and Y2-Y2, respectively. FIGS. 24 and 25 are perpendicular to FIG. 23. The structure 100 may be flipped and portions of the silicon substrate 102 may be removed.

The structure 100 may be turned such that the carrier wafer 168 is now at a lower level and the silicon substrate 102 is at a upper level of the structure for further processing. Remaining processing steps may be done with the structure flipped as described. The remaining drawings show the structure 100 not flipped, with processing steps done at the lower level of the structure 100.

The portions of the silicon substrate 102 may be selectively removed using a combination of processes steps, such as wafer grinding, CMP, RIE and wet etch process. The final stage of the process may include exposing a lower horizontal surface of the etch stop layer 104, and a lower horizontal surface and a vertical side surface of the STI 120.

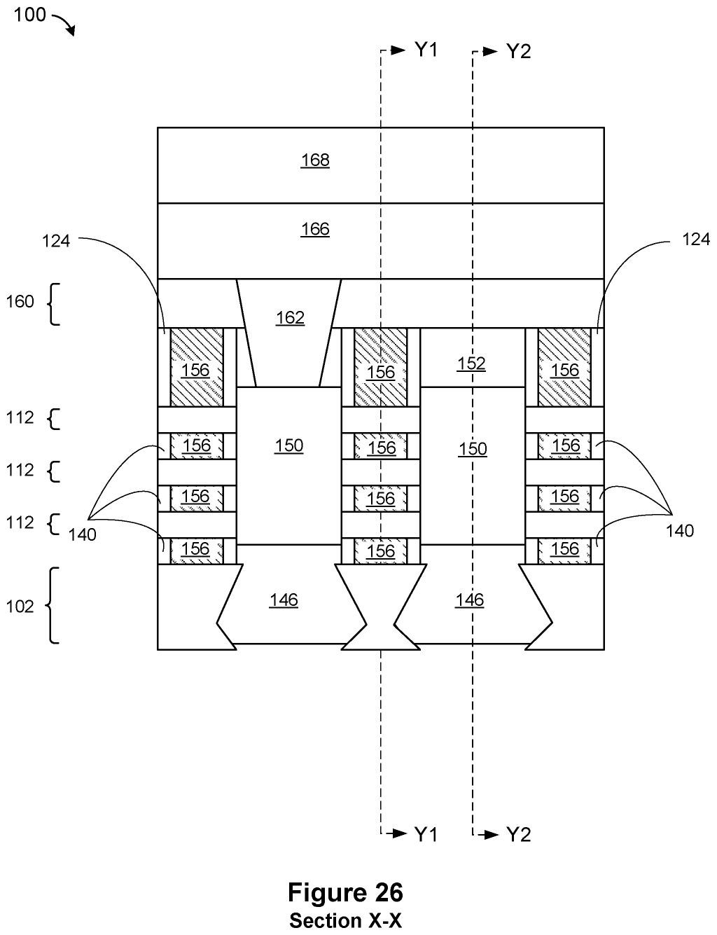

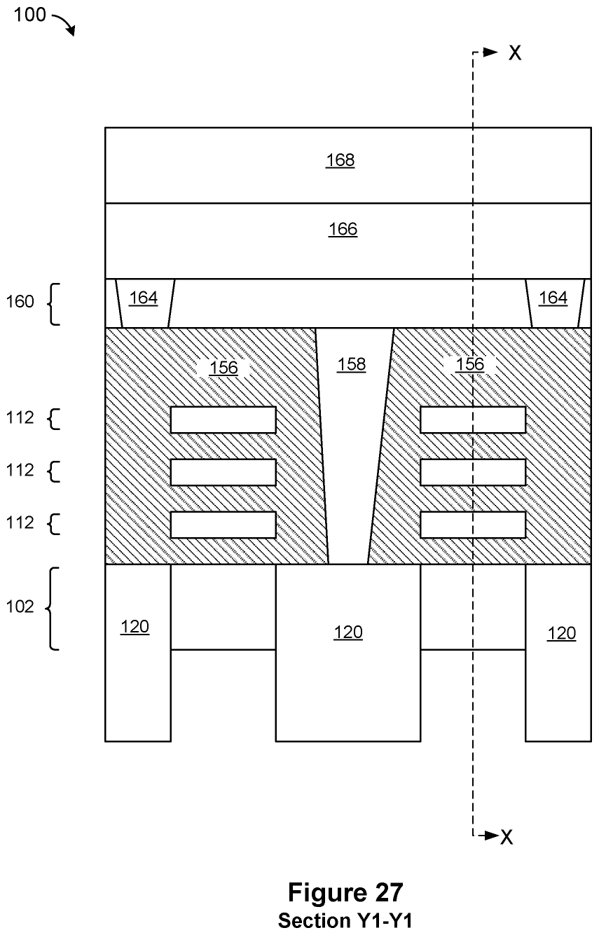

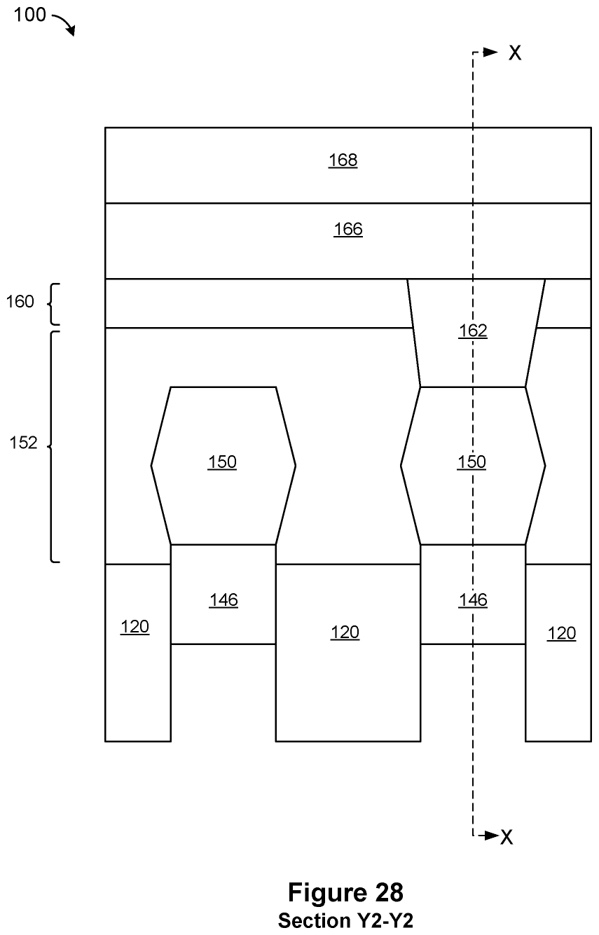

Referring now to FIGS. 26, 27 and 28, the structure 100 is shown according to an exemplary embodiment. FIGS. 26, 27 and 28 are each a cross-sectional view of the structure 100 along section lines X-X, Y1-Y1 and Y2-Y2, respectively. FIGS. 27 and 28 are perpendicular to FIG. 26. The etch stop layer 104 may be removed.

The etch stop layer 104 may be selectively removed using a combination of processes steps, such as RIE and wet etch process. The final stage of the process may include exposing a lower horizontal surface of remaining portions of the silicon substrate 102, and the lower horizontal surface and a vertical side surface of the STI 120.

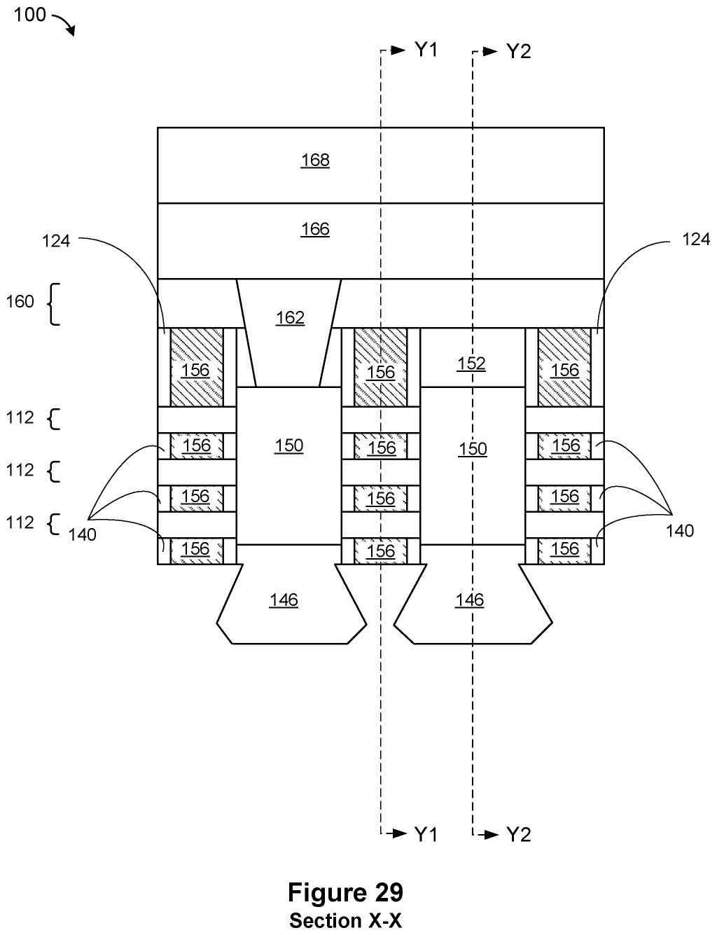

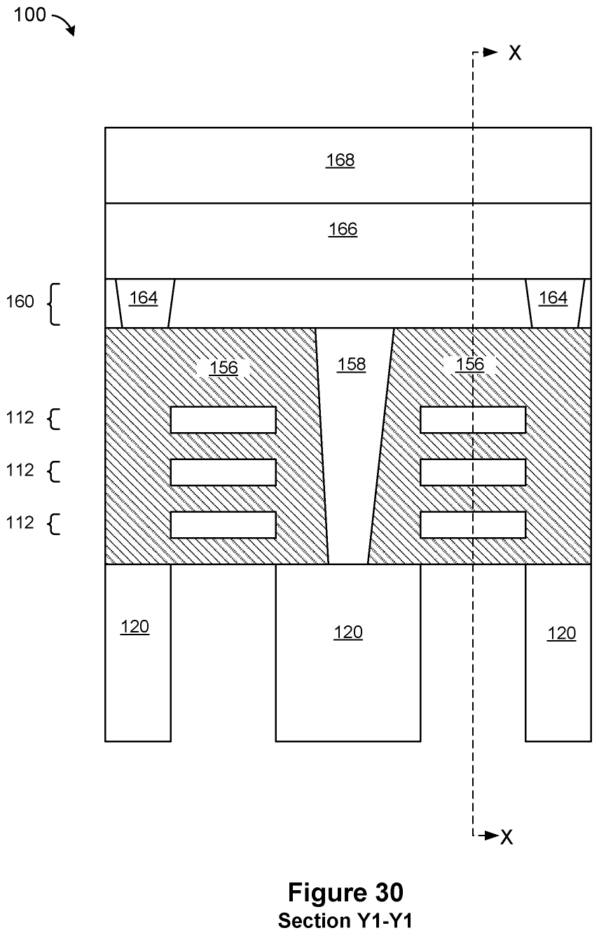

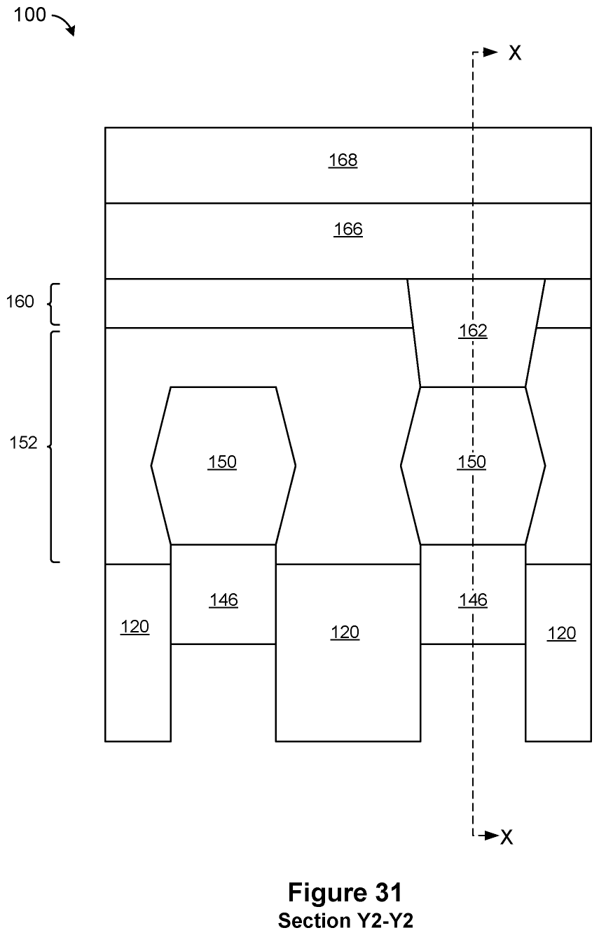

Referring now to FIGS. 29, 30 and 31, the structure 100 is shown according to an exemplary embodiment. FIGS. 29, 30 and 31 are each a cross-sectional view of the structure 100 along section lines X-X, Y1-Y1 and Y2-Y2, respectively. FIGS. 30 and 31 are perpendicular to FIG. 29. The remaining portions of the silicon substrate 102 may be removed.

The remaining portions of the silicon substrate 102 may be selectively removed using a combination of processes steps, such as RIE and wet etch process. The final stage of the process may include exposing a lower horizontal surface of remaining portions of the silicon substrate 102, and the lower horizontal surface and a vertical side surface of the STI 120.

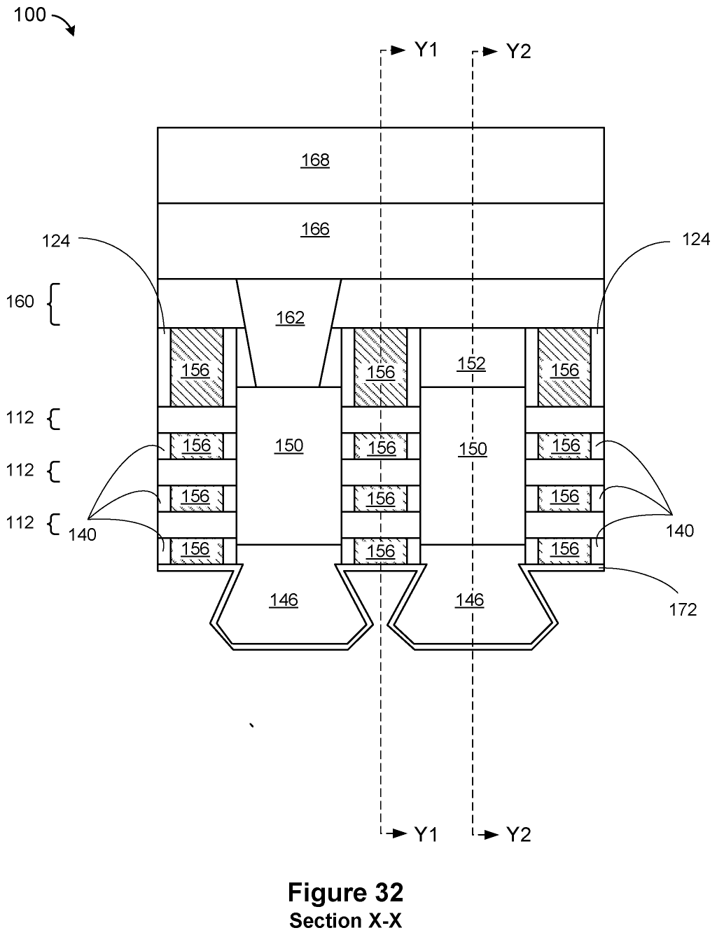

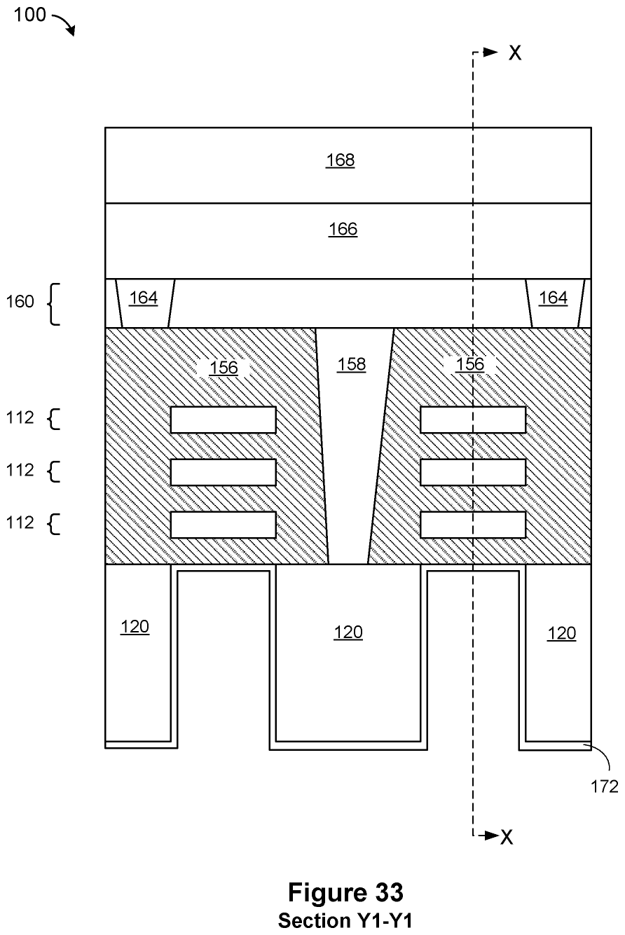

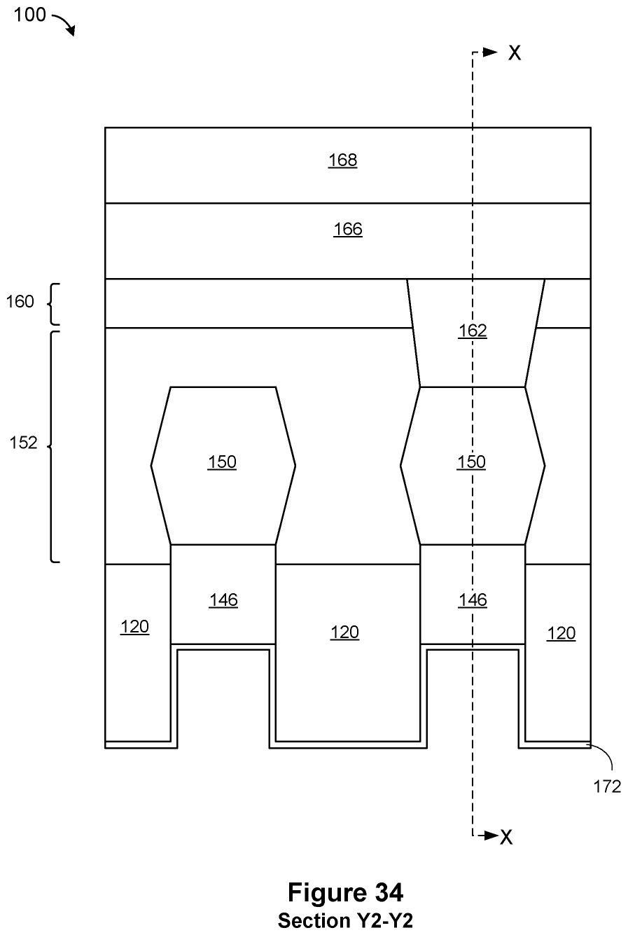

Referring now to FIGS. 32, 33 and 34, the structure 100 is shown according to an exemplary embodiment. FIGS. 32, 33 and 34 are each a cross-sectional view of the structure 100 along section lines X-X. Y1-Y1 and Y2-Y2, respectively. FIGS. 33 and 34 are perpendicular to FIG. 32. A dielectric encapsulation liner 172 may be formed.

The dielectric encapsulation liner 172 may be formed conformally on the structure 100. The dielectric encapsulation liner 172 may be formed on lower horizontal surfaces of a lowermost channel layer 112, the inner spacer 140, the replacement gate 156. The dielectric encapsulation liner 172 may be formed on a lower horizontal surface and a vertical side surface of the STI 120. The dielectric encapsulation liner 172 may be formed on a lower horizontal surface and a vertical side surface of the placeholder 146. The liner may provide protection during subsequent processing steps. The dielectric encapsulation liner 172 may be formed by a conformal deposition process. The dielectric encapsulation liner 172 may include any dielectric material such as silicon nitride and may include a single layer or may include multiple layers of dielectric material. The dielectric encapsulation liner 172 may be 5 nm thick, although a thickness less than or greater than 5 nm may be acceptable.

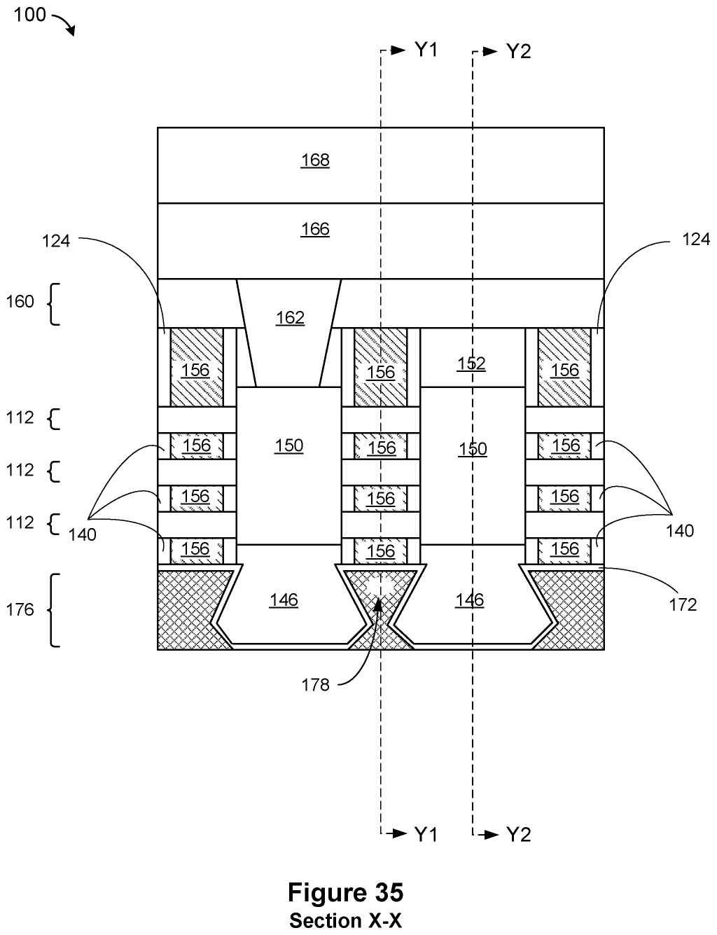

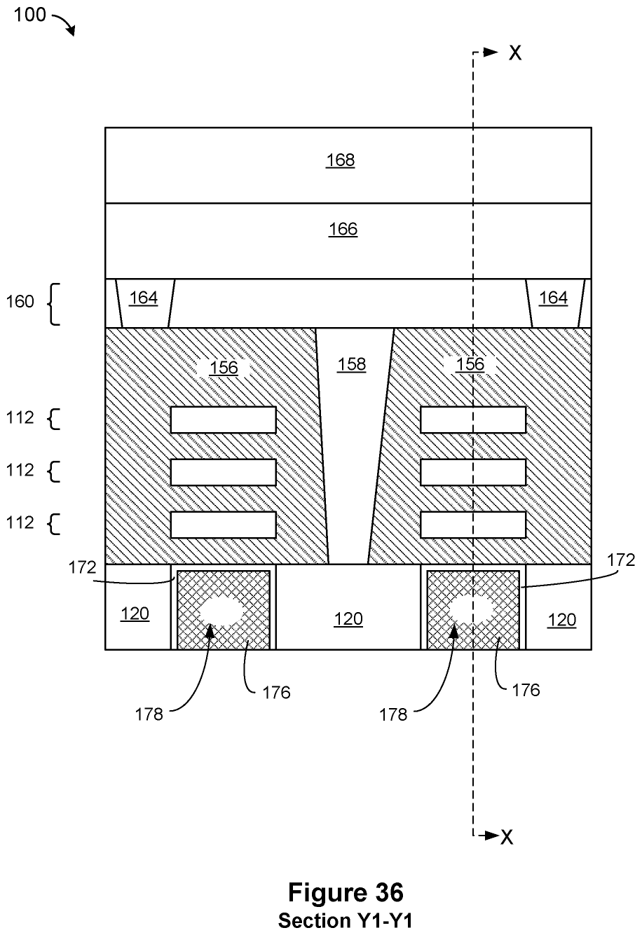

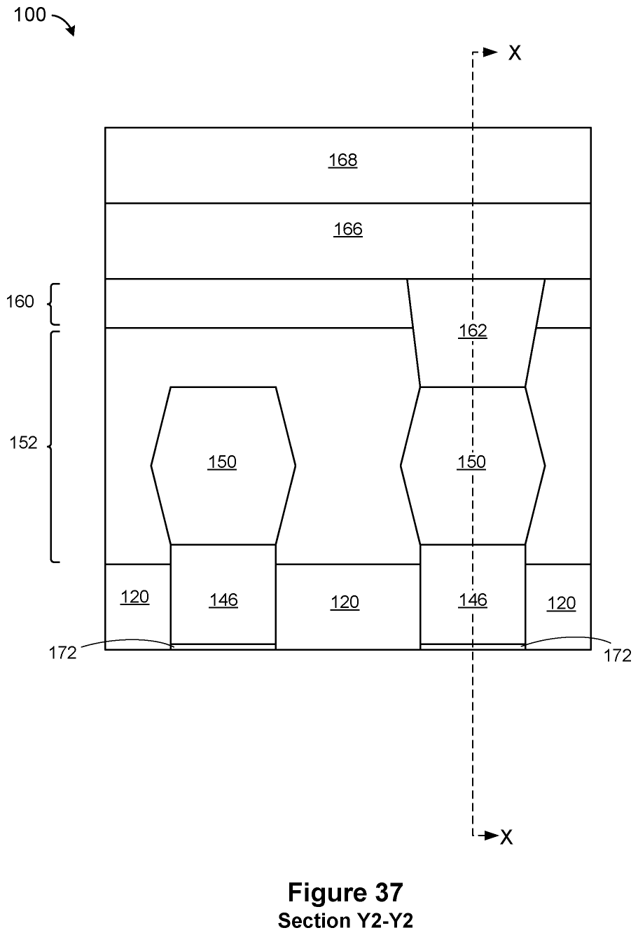

Referring now to FIGS. 35, 36 and 37, the structure 100 is shown according to an exemplary embodiment. FIGS. 35, 36 and 37 are each a cross-sectional view of the structure 100 along section lines X-X. Y1-Y1 and Y2-Y2, respectively. FIGS. 36 and 37 are perpendicular to FIG. 35. A dielectric fill layer 176 may be formed. Portions of the dielectric encapsulation liner 172 and the STI 120 may be removed.

The dielectric fill layer 176 may be formed conformally on the structure 100. The dielectric fill layer 176 may be formed between adjacent STI 120 surrounded by the dielectric encapsulation liner 172, adjacent to a vertical side surface of the STI 120 with the dielectric encapsulation liner 172. The dielectric fill layer 176 may be formed surrounding vertical side surfaces and a lower horizontal surface of below the placeholder 146 surrounded by the dielectric encapsulation liner 172. An air gap 178 may be formed in the dielectric fill layer 176 in an area between adjacent placeholder 146 surrounded by the liner 172. The air gap 178 may be formed in the dielectric fill layer 176 in an area between adjacent STI 120 surrounded by the dielectric encapsulation liner 172. The airgap 178 helps provide capacitance reduction for overall RC reduction between intra-level metal line. The capacitance reduction will enhance device performance.

The dielectric fill layer 176 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by an isotropic etch process such as a wet etch process, or any suitable etch process. In an embodiment, the dielectric fill layer 176 may include one or more layers. In an embodiment, the dielectric fill layer 176 may include any dielectric material such as, an oxide, SiOC, low-k oxide or any combination of these materials.

A chemical mechanical polishing (CMP) technique may be used to remove excess material and polish lower surfaces of the structure 100 during processing, which is physically flipped however still illustrated as a lower horizontal surface of the FIGS. 35-37. A lower horizontal surface of the structure 100 may include a lower horizontal surface of the dielectric fill layer 176, the dielectric encapsulation liner 172 and the STI 120. The dielectric encapsulation liner 172 may remain surrounding the placeholder 146.

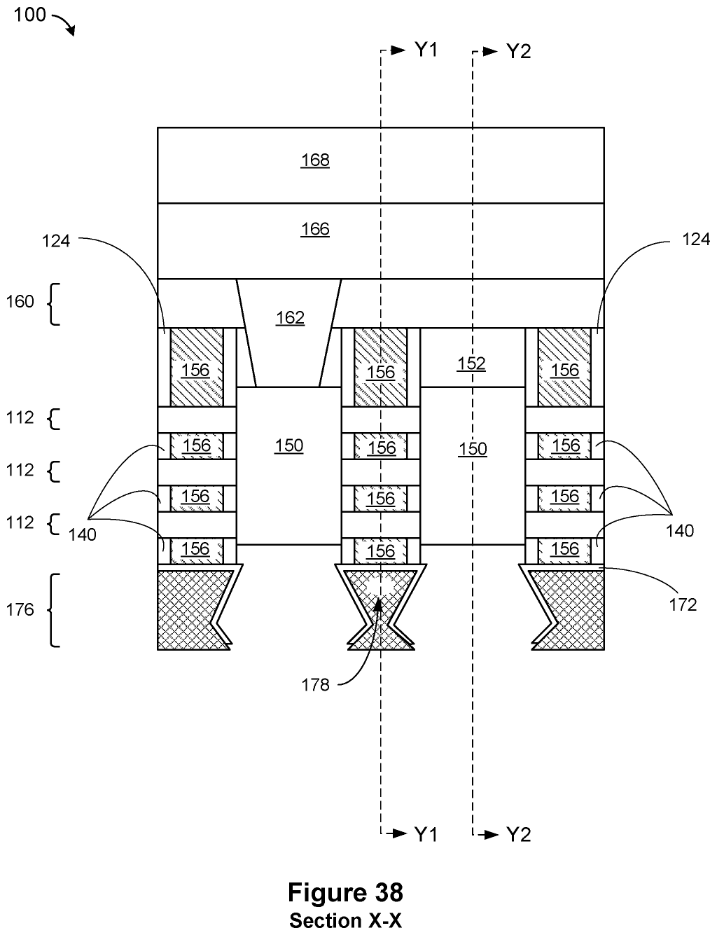

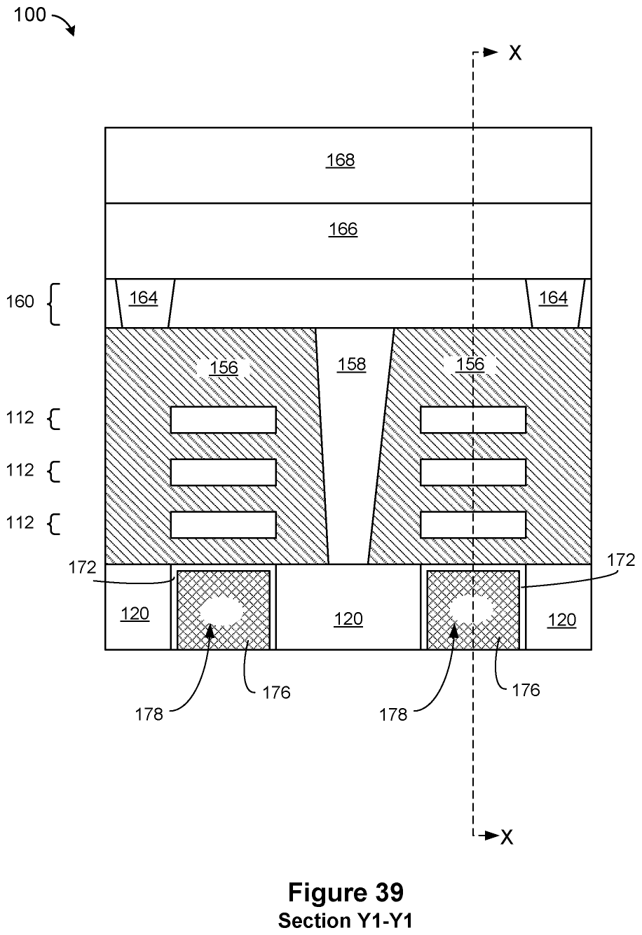

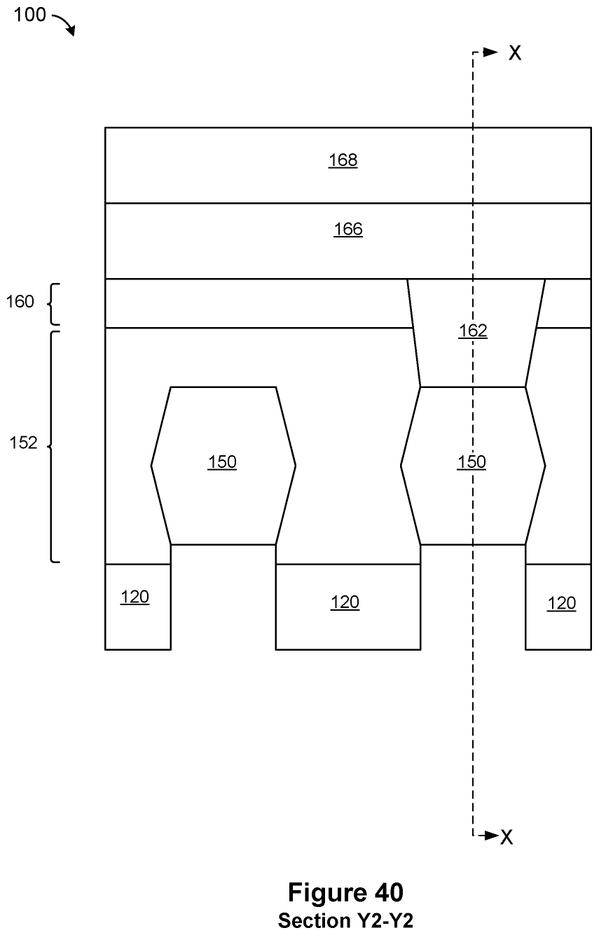

Referring now to FIGS. 38, 39 and 40, the structure 100 is shown according to an exemplary embodiment. FIGS. 38, 39 and 40 are each a cross-sectional view of the structure 100 along section lines X-X, Y1-Y1 and Y2-Y2, respectively. FIGS. 39 and 40 are perpendicular to FIG. 38. Exposed portions of the dielectric encapsulation liner 172 may be removed. The placeholder 146 may be removed.

The portions of the dielectric encapsulation liner 172 may be removed selective to the placeholder 146, the STI 120, the dielectric fill layer 176. For example, a wet or dry etch process can be used with the appropriate chemistry to remove the portions of the dielectric encapsulation liner 172. The material used for the etching process may be selective such that the placeholder 146, the STI 120 and the dielectric fill layer 176 remain and are not etched.

The placeholder 146 may be removed selective to the STI 120, remaining portions of the dielectric encapsulation liner 172, the dielectric fill layer 176, the frontside portion of the source drain 150, the sidewall spacer 140 and the ILD 152. For example, a wet or dry etch process can be used with the appropriate chemistry to remove the placeholder 146. The material used for the etching process may be selective such that the dielectric encapsulation liner 172, the dielectric fill layer 176, the frontside portion of the source drain 150, the sidewall spacer 140 and the ILD 152 remain and are not etched.

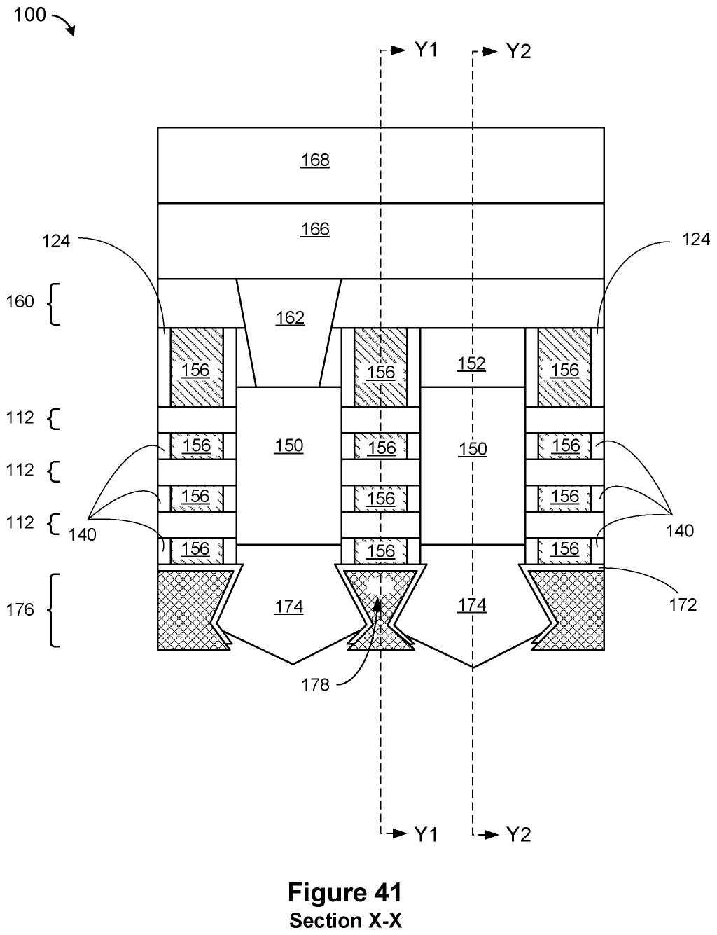

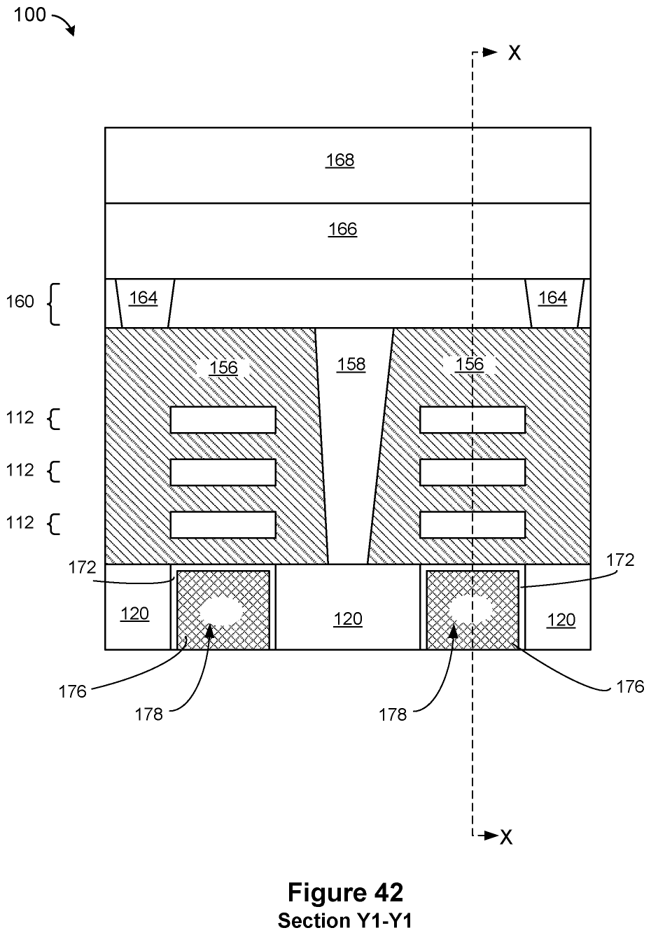

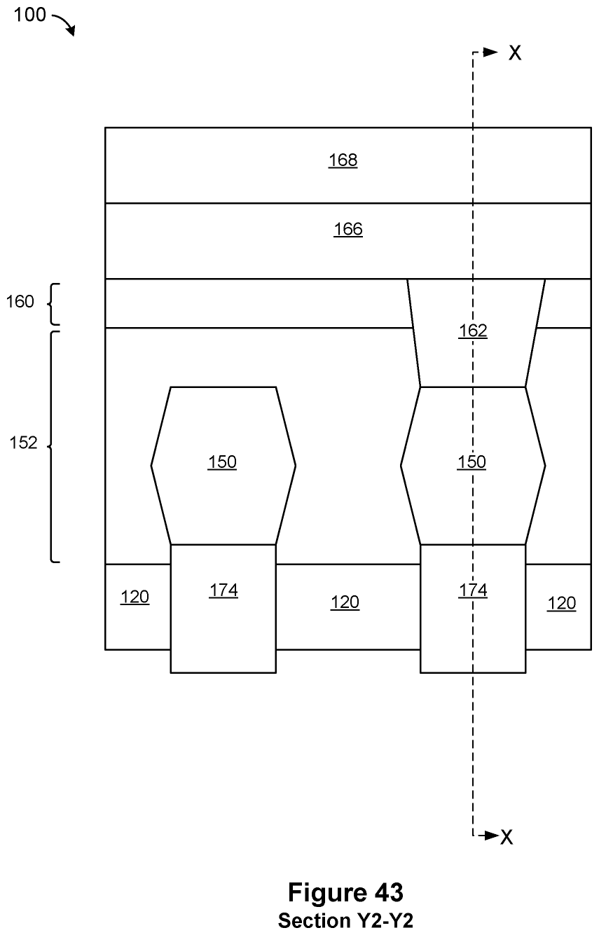

Referring now to FIGS. 41, 42 and 43, the structure 100 is shown according to an exemplary embodiment. FIGS. 41, 42 and 43 are each a cross-sectional view of the structure 100 along section lines X-X, Y1-Y1 and Y2-Y2, respectively. FIGS. 42 and 43 are perpendicular to FIG. 41. A backside portion of the source drain 174 may be formed.

The backside portion of the source drain 174 may be selectively formed where the placeholder 146 was removed. The backside portion of the source drain 174 may be grown from the frontside portion of the source drain 150. An upper horizontal surface of the backside portion of the source drain 174 may be a lower horizontal surface of the frontside portion of the source drain 150. A vertical side surface of the backside portion of the source drain 174 may be a vertical side surface of the dielectric encapsulation liner 172 surrounding the dielectric fill layer 176. A vertical side surface of the backside portion of the source drain 174 may be a vertical side surface of the dielectric encapsulation liner 172 surrounding the STI 120. A vertical side surface of the backside portion of the source drain 174 may be a vertical side surface of a lowermost sidewall spacer 140.

Forming the backside portion of the source drain 174 requires conditions which will not damage the BEOL layers 166 and the replacement gate 156, and requires a low thermal-budget process. The low-thermal-budget process may refer to low-temperature epitaxial processes conducted at temperatures below 450° C. for a duration of minutes. The low-thermal-budget process may also refer to short duration thermal process from about 1 millisecond to about 10's of nanoseconds conducted at a high temperature ranging from 750° C. to 1300° C. A trench epitaxy refers to an epitaxial process of forming or re-forming a surface layer of the frontside portion of the source drain 150 which is drain doped semiconductor through an opening where the placeholder 146 was removed. The trench epitaxy may include a combination of gas-phase epitaxial growth, solid-phase epitaxial re-growth, and liquid phase epitaxial re-growth to form the backside portion of the source drain 174 as described below.

During the gas-phase epitaxial growth, the gaseous precursors are supplied to a lower semiconductor surface of the frontside portion of the source drain 150 and held at a low temperature of 450° C. or less. The gaseous precursors are selected to enable the epitaxial growth of a target semiconductor-dopant alloy at such low temperature. A silicon precursor may include Disilane (Si2H6). A germanium precursor may include Germane (GeH4) and Digermane (Ge2H6). A carbon precursor may include Methane (CH4). A tin precursor may include Tin Tetrachloride (SnC14). A boron precursor may include Diborane (B2H6). A gallium precursor may include Trimethylgallium (TMG). An aluminum precursor may include Trimethylaluminum (TMA). A phosphorus precursor may include Phosphine (PH3). An arsenic precursor may include Arsine (AsH3). These gaseous precursors can be mixed with a neutral carrier gas such as hydrogen H2, helium He, or argon Ar and delivered to the heated substrate to form an epitaxial layer on the lower surface of the frontside portion of the source drain 150. During epitaxial growth on the underlying crystalline source drain semiconductor surface of the frontside portion of the source drain 150, the precursor radicals carrying Group IV elements quickly arrange themselves in a regular periodic matrix aligned to the periodicity of underlying crystalline lattice. A precursor radical carrying dopant element swept to the growing surface of the backside portion of the source drain 174 is then forced to occupy a substitutional lattice site in this periodic arrangement of surface-attached radicals/elements. Effectively, the dopant element is forced to occupy a substitutional lattice site by its neighbors or, equivalently, the growing epitaxial front despite the fact that the substitutional lattice site may not be energetically favorable for the dopant atom. To put it in other words, such substitutionally-placed dopant atoms are metastable with respect to the semiconductor lattice and may precipitate out forming electrically inactive dopant interstitials and clusters, however, the low temperature of epitaxial growth helps preventing this from happening and effectively locks in the dopants in their metastable substitutional sites. As the result, the grown epitaxial layer of the backside portion of the source drain 174 has a large amount of electrically active dopant, or, equivalently a large amount of free electrical carriers such as holes and electrons. Optimization of trench epitaxial process by selecting a set of precursors and varying precursor and carrier gas flow ratios, and process pressure and temperature is directed toward maximizing resultant concentration of free electrons for contacts to n-type semiconductor (n-FET S/D) or free holes for contacts to p-type semiconductor (p-FET S/D). Concentration of free carriers (electrons or holes) in these epitaxial layers of higher than 7e20 cm⁻³ and, in some embodiments, higher than 1e21 cm⁻³ is achievable. In contrast, a more typical thermal dopant activation via high-temperature (above 1000° C.) annealing of doped semiconductors results in concentration of free carriers of from about 2e20 cm⁻³ to about 5e20 cm⁻³ and is not compatible with the temperature sensitive structures present in the substrate. At the low deposition temperature and optimized for maximum free carrier concentration, the epitaxial growth process can be slow and non-selective. In a non-selective process, deposition of semiconductor may occur over the entire substrate surface. In contrast, in a selective deposition process the semiconductor material deposits epitaxially on semiconductor surfaces and generally does not deposit on other exposed surfaces such as dielectric surfaces. However, in one embodiment, a low-temperature epitaxial layer can be made thin in a range of 1-3 nanometers thick or only 2-6 monolayers of epitaxial semiconductor. In this ultra-thin regime, a different speed of nucleating semiconductor material on the surfaces of crystalline semiconducting material and dielectric material may result in different thickness of resultant semiconductor layer formed over these dissimilar surfaces. The resultant semiconductor layer is typically thinner over dielectric surfaces and can be discontinuous or be absent over portions of these surfaces. The thinner, discontinuous semiconductor layer can be removed in an in-situ etching step conducted within the epitaxial growth equipment. This deposition, etch sequence can be repeated multiple times yielding final epitaxial semiconductor layer thickness of from 1 nm to about 10 nm on exposed crystalline surfaces only. The etch step is typically conducted via adding or pulsing HCl (hydrochloric acid) vapors into the growth chamber. In some embodiments, the HCl vapors can be added continuously during the epitaxial growth process to allow for a continuous removal of semiconductor film nucleated on dielectric surfaces. This approach is possible if HCl vapors do not interfere with incorporating electrically active dopants into the epitaxial film.

Exact chemical composition of the trench epitaxial film may vary and several dissimilar chemical compositions may yield the maximum amount of free carriers in the film and a low contact resistivity of the metal-semiconductor interface. Yet, some chemical configurations for these films are more preferred than others leading to even lower contact resistivity of the metal-semiconductor interface. In one embodiment, p-type trench epitaxial layer is grown over p-type semiconductor frontside portion of the source drain 150. The p-type trench epitaxial layer is preferably SiGe with the Ge content from about 50 atomic percent (at. %) to about 95 at. %. Increasing amount of high atomic number (high-Z) germanium in the epi layer leads to a higher pinning of the semiconductor valence band to the adjacent metal Fermi level, thereby, reducing Schottky barrier and contact resistivity of the interface. In some embodiments, even larger (higher-Z) tin (Sn) can be added to SiGe in small amounts (up to about 5 at. %) to further promote this pinning. An additive benefit of using a higher amount of Ge in the trench epi layer is a lower epi growth temperature. Boron can be used as p-type dopant to yield concentration of free holes in the excess of 7e20 cm⁻³ for SiGe trench epi films with Ge amount of less than 66 at. %. However, Boron becomes a less efficient p-type dopant for semiconductors with larger lattice spacing such as SiGe with Ge amount in excess of 60 at. %. Gallium or Aluminum can be added to SiGeB or SiGeSnB films to maximize the free hole concentration, especially, for semiconductors with a larger lattice spacing. The total chemical concentration of p-type dopant in a trench epitaxy surface layer of the epitaxy region 170 is preferably equal to or exceeds 5 at. %, or, equivalently, 2.5e21 cm⁻³.

In another embodiment, n-type trench epitaxial layer is grown over n-type semiconductor frontside portion of the source drain 150. The n-type trench epitaxial layer is preferably Si. In some embodiments, a small amount of Carbon (up to about 1 at. %) can be added to Si to compress its lattice spacing. Phosphorus can be used as an efficient n-type dopant to yield concentration of free electrons in the excess of 7e20 cm⁻³. The total chemical concentration of n-type dopant in the trench epitaxy surface layer of the backside portion of the source drain 174 is preferably equal to or exceeds 5 at. %, or, equivalently, 2.5e21 cm⁻³.

In some embodiments, the backside portion of the source drain 174 may include a solid-phase epitaxial re-growth or a liquid phase epitaxial re-growth, as alluded above. In these approaches, a thin surface semiconductor layer with dopants is first transformed to an amorphous or liquid state and then epitaxially re-grown activating dopants. The physical process of activating dopants is similar to that of low-temperature gas-phase epitaxy but the trapping efficiency of dopants into substitutional lattice sites can be higher due to faster growing epitaxial front. Compatibility to the temperature-sensitive BEOL structures and replacement 156 is achieved through the extreme shortness of the epitaxial re-growth process rather than through a low process temperature. In the liquid phase epitaxial re-growth, the semiconductor surface layer of the lower surface of the frontside portion of the source drain 150 is converted into a liquid state through a nanosecond-scale laser annealing that raises surface temperature above the melting point for 10's to 100's of nanoseconds. The surface semiconductor layer of the lower surface of the frontside portion of the source drain 150 may have a different melting point than the rest of the frontside portion of the source drain 150 such as the case of SiGe with a high at. % Ge. For instance, SiGe with 70 at. % Ge has the melting point of 1160° C., whereas SiGe with 50 at. % Ge has the melting point of 1270° C. After laser exposure, the surface cools with the speed of about billion degrees per second resulting in an epitaxial re-growth of the liquid layer with the epitaxial front speed of about meter per second. In the solid phase epitaxial re-growth, the semiconductor surface layer is first converted into an amorphous layer through an implantation process. Implantation may employ ions of electrically neutral elements such as Si, Ge, Ar, Xe or dopants such as Ga (for p-type semiconductor) and P (for n-type semiconductor). The ion implantation energy can be adjusted to yield a desired amorphous layer thickness in the range of 1 nm to 10 nm. The implantation process can be conducted at sub room temperature (e.g. at −100° C.) to enhance amorphization efficiency. The semiconductor amorphous layer is then epitaxially re-grown through a microsecond-scale annealing that raises surface temperature above 750° C. for 10's to 100's of microseconds. Low annealing temperature requires longer annealing duration for full epitaxial re-growth but the annealing process remains compatible with the temperature-sensitive structures. The surface heats and cools with the speed of millions degrees per second resulting in an epitaxial re-growth of the amorphous layer with the epitaxial front speed of about millimeter per second. While substantially slower than the epitaxial front speed of the liquid phase epitaxial re-growth, it is still much faster than the speed of low-temperature gas phase epitaxy at about angstroms per second. It is this fast epitaxial growth and fast temperature quench that may yield concentration of free electrons or holes in the trench epitaxial layer in the excess of 1e21 cm⁻³.

The backside portion of the source drain 174 may partially fill the opening where the placeholder 146 was removed. The backside portion of the source drain 174 is made compatible to the respective frontside portion of the source drain 150, that is, if the frontside portion of the source drain 150 is n-type (n-FET), then the backside portion of the source drain 174 is also n-type for n-FET contact, if the frontside portion of the source drain 150 is p-type (p-FET), then the backside portion of the source drain 174 is also p-type for p-FET contact.

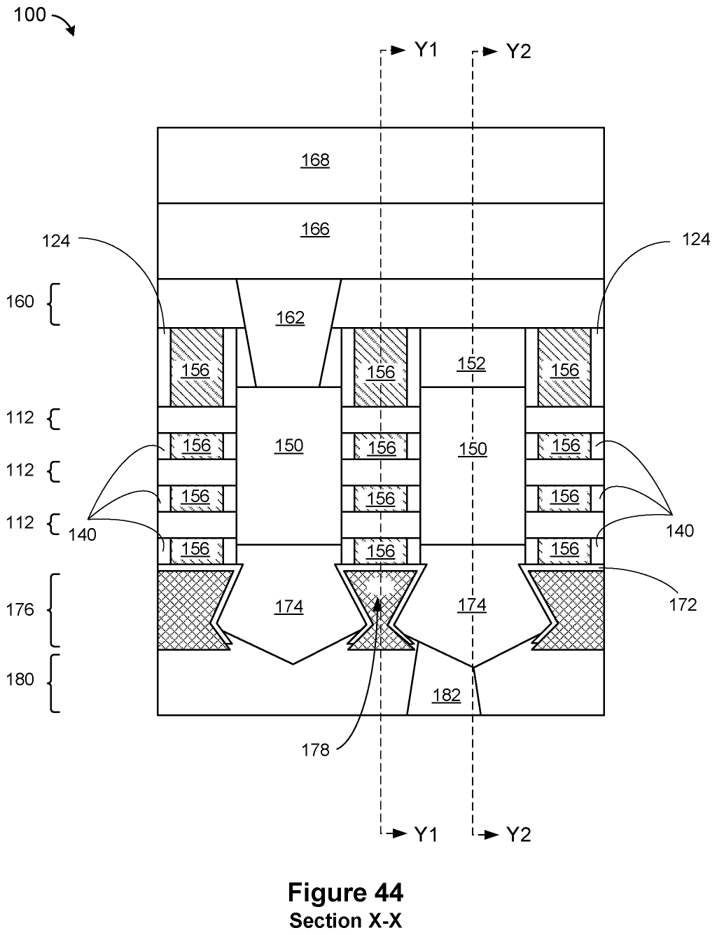

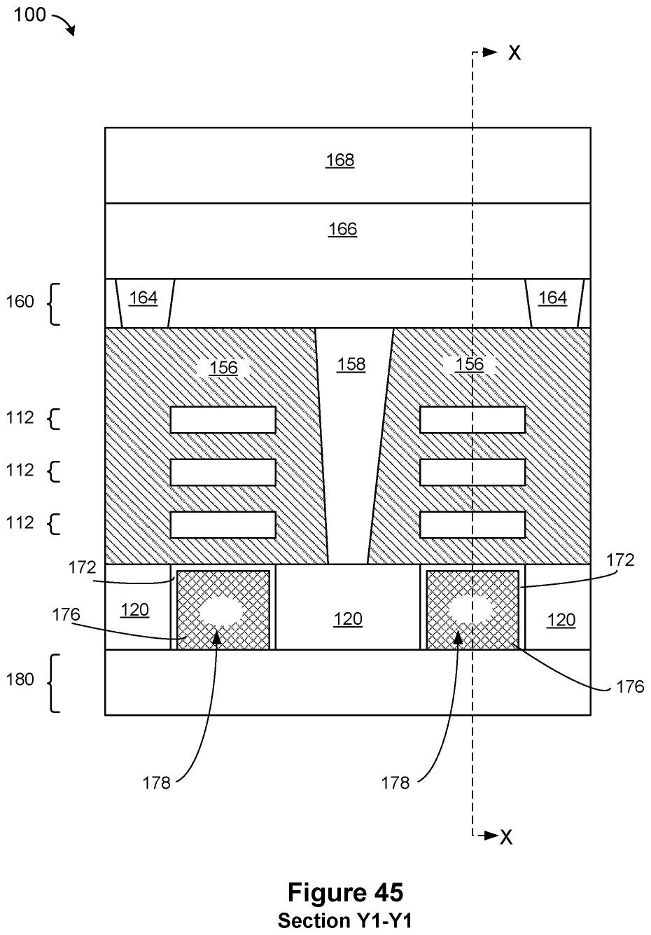

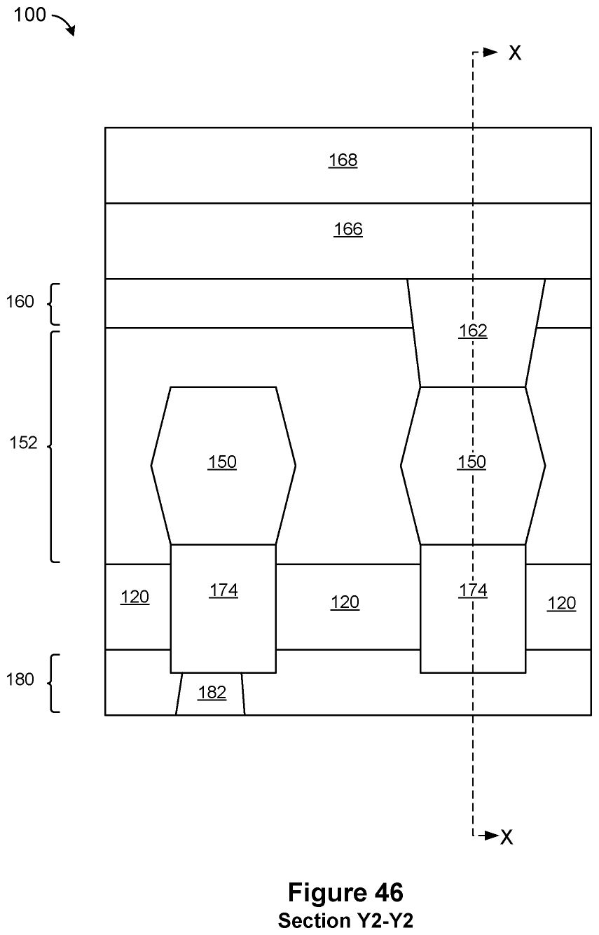

Referring now to FIGS. 44, 45 and 46, the structure 100 is shown according to an exemplary embodiment. FIGS. 44, 45 and 46 are each a cross-sectional view of the structure 100 along section lines X-X, Y1-Y1 and Y2-Y2, respectively. FIGS. 45 and 46 are perpendicular to FIG. 44. An inter-layer dielectric (hereinafter “ILD”) 180 may be formed. A backside contact 182 may be formed.

The ILD 180 may be formed by conformally depositing or growing a dielectric material, as described for the ILD 152. An upper horizontal surface of the ILD 180 may be adjacent to lower horizontal surfaces of the dielectric fill layer 176, the dielectric encapsulation liner 172 and the STI 120. An upper horizontal surface of the ILD 180 may be adjacent to a lower horizontal and a vertical side surface of the backside portion of the source drain 174. A chemical mechanical polishing (CMP) technique may be used to remove excess material and polish lower surfaces of the structure 100.

The backside contact 182 may be each be formed in an opening (not shown) in the ILD 180. The backside contact 182 may be physically and electrically connected to the backside portion of the source drain 174 which is connected to the frontside portion of the frontside portion of the source drain 150. As shown in FIGS. 44 and 46, there is one backside contact 182. There may be any number of backside contacts 182 on the structure 100.

The backside contact 182 may be made to the frontside portion of a source drain 150 which does not have a contact 162. The frontside portion of the source drain 150 may have either a contact 162 or a backside contact 182. This provides more options for a source drain contact.

In an embodiment, a source/drain region which needs to be wired to a signal may have a frontside contact 162 and a source/drain region which needs to be wired to power may have a backside contact 182.

Forming the backside contact 182 involves filling an opening (not shown) with highly-conductive metallic materials. Individual metallic materials within the backside contact 182 are not shown for clarity. While the bulk of the backside contact 182 includes an elemental metal such as W. Co. Ru, or Mo to reduce its bulk resistivity, the metallic compound directly adjacent to the semiconductor of the backside portion of the source drain 174 is selected to reduce the contact resistance between the backside contact 182 and the semiconductor of the trench epitaxy 174. In one embodiment, the metallic compound adjacent to the semiconductor of the trench epitaxy 174 is a metal silicide or germanosilicide. This compound can be created by reacting an elemental metal such as Titanium with the semiconductor of the backside portion of the source drain 174. While metal silicide/germanosilicide is made thin, typically less than 3 nm, it sets the Schottky barrier of the semiconductor-metal interface and, ultimately, the contact resistivity of the interface. The metal silicide/germanosilicide may be separated from the elemental metal fill of the backside contact 182 by a thin conductive metallic liner such as Titanium Nitride liner. High concentration of free carriers in the semiconductor of the backside portion of the source drain 174 and a low Schottky barrier between the metal silicide/germanoslicide and the semiconductor of the epitaxy region 170 allows for a low contact resistivity of about 10⁻⁹ W·cm² for the backside contact structure to both n-type and p-type semiconductors. Presence of multiple metallic compounds within the backside contact 182 does not affect much its series resistance because additional interfacial compounds and liners are made thin in comparison to the elemental metal fill and each metal-metal interfacial resistance is at least an order of magnitude lower than that of semiconductor-metal interface.

A contact resistivity of the backside portion of the source drain 174 to the adjacent metallic compound of the backside contact 182 may be equal to or less then 1e-9 Ohm cm². A volume concentration of free electrical carriers (electrons or holes) of the backside portion of the source drain 174 may be equal to or more than 7e20 cm⁻³. In comparison, a contact resistively of the source drain 174 to the contact 162 may be greater than or equal to 2e-9 Ohm cm². A volume concentration of free electrical carriers (electrons or holes) of the frontside portion of the source drain 150 may be less than or equal to 5e20 cm⁻³.

A chemical mechanical polishing (CMP) technique may be used to remove excess material and polish lower surfaces of the structure 100. A lower surface of the structure 100 may include a lower horizontal surface of the ILD 180 and a lower horizontal surface of the backside contact 182.

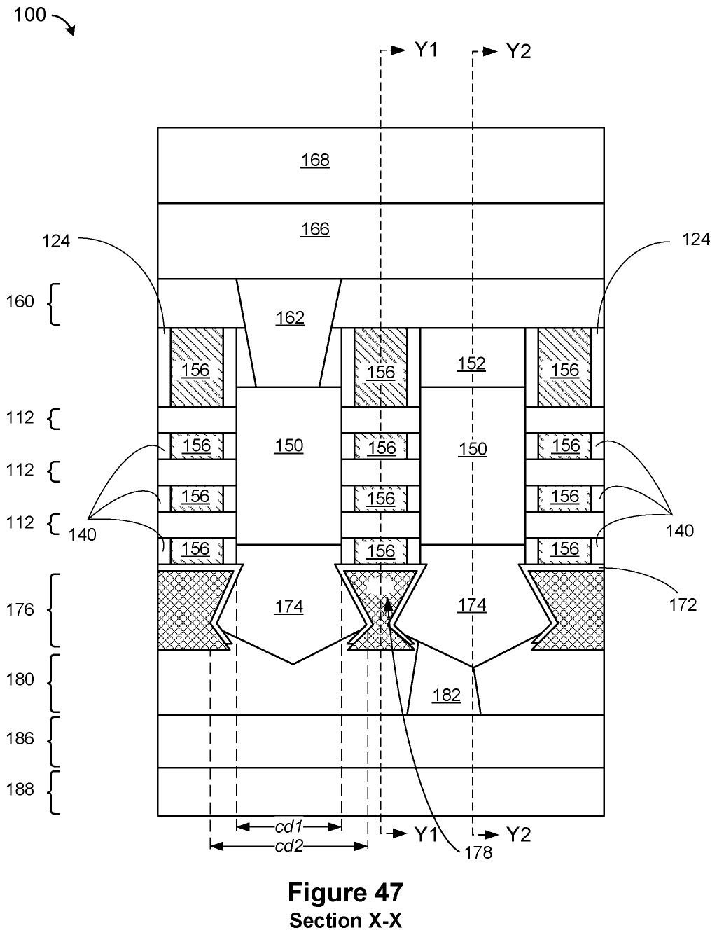

Referring now to FIGS. 47, 48 and 49, the structure 100 is shown according to an exemplary embodiment. FIGS. 44, 45 and 46 are each a cross-sectional view of the structure 100 along section lines X-X, Y1-Y1 and Y2-Y2, respectively. FIGS. 45 and 46 are perpendicular to FIG. 44. An inter-layer dielectric (hereinafter “ILD”) 184 may be formed. A backside power rail (hereinafter “BPR”) 186 and a backside power delivery network (hereinafter “BSPDN”) 188 may be formed.

The ILD 184 may be formed by conformally depositing or growing a dielectric material, as described for the ILD 152. An upper horizontal surface of the ILD 184 may be adjacent to lower horizontal surfaces of the backside contact 182 and the ILD 180. A chemical mechanical polishing (CMP) technique may be used to remove excess material and polish lower surfaces of the structure 100.

The BPR 186 may be formed in openings (not shown) in the ILD 184 using known techniques. In an embodiment, the BPR 186 may be parallel to section line X-X and perpendicular to section line Y-Y. An upper horizontal surface of the BPR 186 may be adjacent to a lower horizontal surface of the backside contact 182. There may be any number of BPRs 186 in the structure 100.

The BSPDN 188 may be formed on the ILD 184 and on the BPR 186. The BSPDN 188 may include additional layers of wiring and vias formed above the existing structure, below the ILD 184 and on the BPR 186. In an embodiment, the BSPDN 188 may include 12 or more layers of lines and visas. The BSPDN 188 may be formed using known techniques.

As shown in FIG. 47, a critical dimension or a width of the backside portion of the source drain 174, cd2, is larger than a critical dimension or a width of the upper portion of the source drain 150, cd1. The larger CD of the backside portion of the source drain, cd2, increases an overlap contact area for forming the backside contact 182 to the backside portion of the source drain 174, improving reliability of the BSCA of the backside contact 182. The air gap 178 helps provide capacitance reduction for overall RC reduction by forming airgap between intra-level metal line connects to each of the backside portions of the source drain 174. The capacitance reduction will enhance device performance. The dielectric encapsulation liner 172 provides separates the dielectric fill layer 176 from the backside portion of the source drain 174. The dielectric encapsulation liner 172 also separates dielectric fill layer 176 from a lowermost channel layer 112 of the nanosheet FET.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor device comprising:
an upper portion of a source drain epitaxy adjacent to semiconductor channel layers of a nanosheet stack on a substrate; and
a lower portion of the source drain epitaxy below the upper portion of the source drain epitaxy, wherein
a second width of the lower portion of the source drain epitaxy is greater than a first width of the upper portion of the source drain epitaxy.

2. The semiconductor device according to claim 1, further comprising:
a dielectric fill layer below the nanosheet stack; and
a dielectric encapsulation liner between the dielectric fill layer and the lower portion of the source drain epitaxy.

3. The semiconductor device according to claim 2, further comprising:
the dielectric encapsulation liner between the dielectric fill layer and the lowest channel layer of the nanosheet stack.

4. The semiconductor device according to claim 2, further comprising:
an air gap in the dielectric fill layer between adjacent lower portions of the source drain epitaxy.

5. The semiconductor device according to claim 1, wherein
the lower portion of the source drain epitaxy comprises a volume concentration of free electrical carriers equal to or more than 7e20 cm⁻³.

6. The semiconductor device according to claim 1, wherein
the nanosheet stack comprises a set of semiconductor channel layers vertically aligned and stacked one on top of another, the set of semiconductor channel layers separated from each other by a gate stack material surrounding the set of semiconductor channel layers.

7. The semiconductor device according to claim 1, further comprising:
a gate cut dielectric between adjacent nanosheet stacks.

8. A semiconductor device comprising:
an upper portion of a source drain epitaxy adjacent to channel layers of a nanosheet stack on a substrate;
a lower portion of the source drain epitaxy below the upper portion of the source drain epitaxy, wherein
a second width of the lower portion of the source drain epitaxy is greater than a first width of the upper portion of the source drain epitaxy;
a dielectric fill layer below the nanosheet stack; and
a dielectric encapsulation liner between the dielectric fill layer and the lower portion of the source drain epitaxy.

9. The semiconductor device according to claim 8, further comprising:
the dielectric encapsulation liner between the dielectric fill layer and the lowest channel layer of the nanosheet stack.

10. The semiconductor device according to claim 8, further comprising:
an air gap in the dielectric fill layer between adjacent lower portions of the source drain epitaxy.

11. The semiconductor device according to claim 8, wherein
the lower portion of the source drain epitaxy comprises a volume concentration of free electrical carriers equal to or more than 7e20 cm⁻³.

12. The semiconductor device according to claim 8, wherein
the nanosheet stack comprises a set of semiconductor channel layers vertically aligned and stacked one on top of another, the set of semiconductor channel layers separated from each other by a gate stack material wrapping around the set of semiconductor channel layers.

13. The semiconductor device according to claim 8, further comprising:
a gate cut dielectric between adjacent nanosheet stacks.

14. A method comprising:
forming an upper portion of a source drain epitaxy adjacent to semiconductor channel layers of a nanosheet stack on a substrate; and
forming a lower portion of the source drain epitaxy below the upper portion of the source drain epitaxy, wherein
a second width of the lower portion of the source drain epitaxy is greater than a first width of the upper portion of the source drain epitaxy.

15. The method according to claim 14, further comprising:
forming a dielectric fill layer below a lowest semiconductor channel layer of the nanosheet stack; and
forming a dielectric encapsulation liner between the dielectric fill layer and the lower portion of the source drain epitaxy.

16. The method according to claim 15, further comprising:
forming the dielectric encapsulation liner between the dielectric fill layer and the lowest channel layer of the nanosheet stack.

17. The method according to claim 15, further comprising:
forming an air gap in the dielectric fill layer between adjacent lower portions of the source drain epitaxy.

18. The method according to claim 14, wherein
the lower portion of the source drain epitaxy comprises a volume concentration of free electrical carriers equal to or more than 7e20 cm⁻³.

19. The method according to claim 14, wherein
the nanosheet stack comprises a set of semiconductor channel layers vertically aligned and stacked one on top of another, the set of semiconductor channel layers separated from each other by a gate stack material wrapping around the set of semiconductor channel layers.

20. The method according to claim 14, further comprising:
forming a gate cut dielectric between adjacent nanosheet stacks.
